(19) United States
(12) Patent Application Publication
(10) Pub. No.: US 2020/0192168 A1
(43) Pub. Date: Jun. 18, 2020

(54) THIN FILM TRANSISTOR SUBSTRATE, DISPLAY APPARATUS, AND LIQUID CRYSTAL DISPLAY

(71) Applicant: Mitsubishi Electric Corporation, Tokyo (JP)

(72) Inventors: Koji ODA, Kumamoto (JP); Kazunori INOUE, Kumamoto (JP)

(73) Assignee: Mitsubishi Electric Corporation, Tokyo (JP)

(21) Appl. No.: 16/703,538

(22) Filed: Dec. 4, 2019

(30) Foreign Application Priority Data
Dec. 13, 2018 (JP) 2018-233279

(51) Int. Cl. G02F 1/1362; H01L 27/12; H01L 27/02; H01L 29/417; G02F 1/1368

(52) U.S. Cl. CPC G02F 1/136204; H01L 27/1248; G02F 1/1368; H01L 29/41733; H01L 27/0266

(57) ABSTRACT

A TFT included in a pixel unit and a protection circuit unit includes a gate insulating layer covering a gate electrode and gate wiring, and a channel layer overlapped with the gate electrode on a gate insulating layer in plan view. The TFT included in the pixel unit includes a channel protective layer covering the channel layer, and a source electrode and a drain electrode is partially overlapped with the channel protective layer and being in contact with the channel layer. The TFT included in the protection circuit unit includes: a source electrode and a drain electrode being in contact with the channel layer and mutually separately disposed; and a protective insulating layer being in contact with the channel layer and covering the source electrode, the drain electrode, and the channel protective layer. A pixel electrode electrically connected to the drain electrode is included in the pixel unit.

### BACKGROUND OF THE INVENTION

### Field of the Invention

The present invention relates to a thin film transistor substrate including a TFT using an oxide semiconductor, a display apparatus, and a liquid crystal display.

### Description of the Background Art

Thin film transistors (TFTs) have characteristics of low power consumption and thinness, and are actively applied to electronic devices. Further, there has been used a thin film transistor substrate (hereinafter also referred to as “TFT array substrate”) in which TFTs as thin film transistors are arranged in an array and used as a switching element, for example, for a display apparatus (electro-optical apparatus) using liquid crystal or organic electro-luminescence (EL).

Electro-optical elements for a liquid crystal display (LCD) include a simple matrix LCD and a TFT-LCD using a TFT as a switching element. Among these, TFT-LCDs are widely used as displays or monitors for mobile computers, personal computers, televisions, and the like.

As a driving method of liquid crystal in the LCD, there are a horizontal electric field system such as twisted nematic (TN) system, in plane switching (IPS) system for high contrast and wide viewing angle, and fringe field switching (FFS) system (“IPS” is a registered trademark of Japan Display Inc.). The IPS liquid crystal display is of a display method that performs display by applying a horizontal electric field to liquid crystal sandwiched between opposing substrates. In the IPS liquid crystal display, since a pixel electrode to apply a horizontal electric field and a common electrode are provided in a same layer, liquid crystal molecules located above the pixel electrode are not driven sufficiently, which lowers transmittance. Whereas, the FFS system can drive liquid crystal molecules located above the pixel electrode by a fringe electric field, and thus has better transmittance than the IPS system.

The matrix TFT-LCD described above is usually configured such that a display material such as liquid crystal is sandwiched between two opposing substrates, and a voltage is selectively applied to the display material. At least one of the substrates is the TFT array substrate described above. On this array substrate, switching elements such as TFTs, and source wiring and gate wiring for supplying signals to the switching elements are formed in an array.

However, since TFT array substrates are often insulating substrates such as glass, a dielectric breakdown short circuit easily occurs between the source wiring and the gate wiring, for example, due to static electricity generated in a manufacturing process. Typically, as means for overcoming this problem, low-resistance wiring called short ring wiring is arranged in a peripheral portion on the TFT array substrate. For example, Japanese Patent No. 5080172, Japanese Patent Application Laid-Open No. 2010-92036, and Japanese Patent No. 5984905 disclose that each piece of wiring of the source wiring and the gate wiring is held at a same potential by connecting between the low-resistance wiring and the source wiring, and between the low-resistance wiring and the gate wiring through a bidirectional diode for a protection circuit.

A diode of a protection circuit unit requires a high resistance value to some extent. In order to drive a display apparatus, a voltage of 20 V or more to 30 V or less is usually required. When a current flows through the diode at a voltage that is normally applied, a desired voltage is not applied to the pixel, and display abnormality occurs. In order to suppress such problems, it is necessary to increase a diode resistance by increasing a channel length or decreasing a channel width.

In a case of a conventional diode using amorphous silicon, the amorphous silicon film itself has high resistance. Therefore, by individually setting a channel length and a channel width of the diode to about 5 μm or more and 10 μm or less, it is possible to obtain a diode resistance that does not particularly cause a problem in display.

However, in recent years, TFTs using an oxide semiconductor have been used in place of the conventionally used amorphous silicon TFTs, in order to achieve higher definition and a built-in drive circuit unit. Oxide semiconductors are expected as next-generation materials with high mobility. As an oxide semiconductor, there are a zinc oxide (ZnO)-based material, an amorphous InGaZnO-based material in which gallium oxide (Ga₂O₃) and indium oxide (In₂O₃) are added to zinc oxide, and the like.

Since oxide semiconductors have about two orders higher mobility and higher carrier concentration than amorphous silicon films, a diode resistance of diodes using oxide semiconductors is two or three orders lower than that using amorphous silicon. In order to increase the diode resistance, it is necessary to increase the channel length, and in order to obtain a desired resistance value, it is necessary to increase the channel length to several tens μm or more to 100 μm or less. Increasing the channel length leads to enlargement of the diode, which accordingly increases an area of a frame region, making it difficult to narrow the frame region.

### SUMMARY

An object of the present invention is to provide a technique capable of reducing an occupied area of a protection circuit unit and narrowing a frame, in a thin film transistor substrate.

A thin film transistor substrate according to the present invention includes a glass substrate, a pixel unit, and a protection circuit unit. The pixel unit is disposed on a glass substrate. The protection circuit unit is disposed on the glass substrate and protects the pixel unit from electrostatic breakdown. Both the pixel unit and the protection circuit unit include a thin film transistor. The thin film transistor included in the pixel unit and the protection circuit unit includes: a gate electrode and gate wiring disposed on the glass substrate; a gate insulating layer covering the gate electrode and the gate wiring; and a channel layer overlapped with the gate electrode in plan view on the gate insulating layer. The thin film transistor included in the pixel unit includes: a channel protective layer covering a channel layer; and a first source electrode and a first drain electrode that are overlapped with a part of the channel protective layer and are in contact with the channel layer. The thin film transistor included in the protection circuit unit includes: a second source electrode and a second drain electrode that are in contact with the channel layer and disposed to be spaced apart from each other; and a protective insulating layer that is in contact with the channel layer and covers the second source electrode, the second drain electrode, and the channel protective layer. The thin film transistor substrate includes a pixel electrode electrically connected to the first drain electrode in the pixel unit.

Since the thin film transistor included in the protection circuit unit does not include a channel protective layer, a carrier concentration of the channel layer of the protection circuit unit can be made lower than a carrier concentration of the channel layer of the pixel unit, for example, by performing oxidation treatment after forming the source electrode and the drain electrode. This can increase the diode resistance when the thin film transistor included in the protection circuit unit is diode-connected, enabling reduction of the channel length. As a result, an occupied area of the protection circuit unit is reduced, and the frame can be narrowed.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are plan views of a drive circuit unit, a pixel unit, and a protection circuit unit included in a TFT array substrate according to a first preferred embodiment;

FIGS. 2A and 2B are cross-sectional views of the drive circuit unit, the pixel unit, and the protection circuit unit included in the TFT array substrate according to the first preferred embodiment;

FIGS. 3A and 3B to FIGS. 8A and 8B are cross-sectional views each illustrating a manufacturing process of the TFT array substrate;

FIGS. 9A and 9B to FIGS. 14A and 14B are plan views each illustrating a manufacturing process of the TFT array substrate;

FIG. 15 is a graph showing an Id-Vg curve of a TFT of the protection circuit unit;

FIGS. 16A to 16C are cross-sectional views of a drive circuit unit, a pixel unit, and a protection circuit unit included in a TFT array substrate according to a second preferred embodiment;

FIGS. 17A and 17B are plan views of the drive circuit unit, the pixel unit, and the protection circuit unit included in the TFT array substrate according to the second preferred embodiment;

FIGS. 18A and 18B are cross-sectional views of a drive circuit unit, a pixel unit, and a protection circuit unit included in a TFT array substrate according to a third preferred embodiment;

FIGS. 19A and 19B are plan views of the drive circuit unit, the pixel unit, and the protection circuit unit included in the TFT array substrate according to the third preferred embodiment;

FIGS. 20A and 20B to FIGS. 27A and 27B are cross-sectional views each illustrating a manufacturing process of a TFT array substrate;

FIGS. 28A and 28B to FIGS. 35A and 35B are plan views each illustrating a manufacturing process of the TFT array substrate;

FIGS. 36A and 36B are cross-sectional views of a drive circuit unit, a pixel unit, and a protection circuit unit included in a TFT array substrate according to a fourth preferred embodiment;

FIGS. 37A and 37B are plan views of the drive circuit unit, the pixel unit, and the protection circuit unit included in the TFT array substrate according to the fourth preferred embodiment;

FIG. 38 is a circuit diagram of a TFT array substrate included in a liquid crystal display according to a related art;

FIG. 39 is a circuit diagram of a diode configured by connecting a gate electrode and a source electrode of a TFT; and

FIG. 40 is a circuit diagram of a protection circuit unit.

### DESCRIPTION OF THE PREFERRED EMBODIMENTS

### Related Art

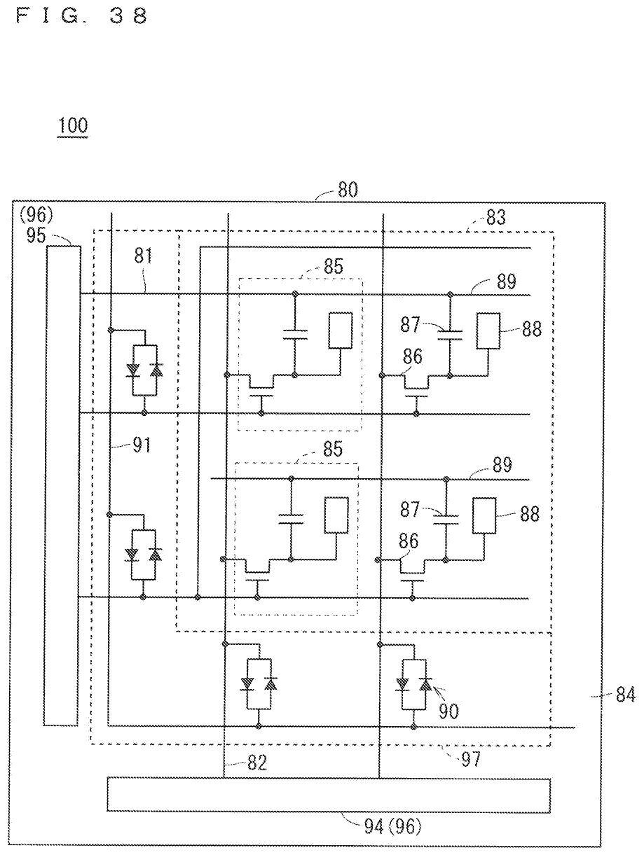

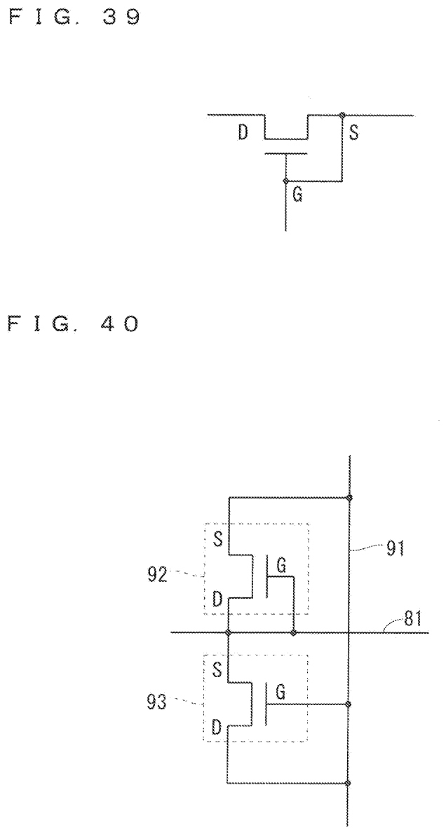

Prior to describing preferred embodiments of the present invention, a related art of the present invention will be described. FIG. 38 is a circuit diagram of a TFT array substrate 100 included in a liquid crystal display according to the related art. FIG. 39 is a circuit diagram of a diode configured by connecting a gate electrode and a source electrode of a TFT. FIG. 40 is a circuit diagram of a protection circuit unit 97.

As illustrated in FIG. 38, the TFT array substrate 100 includes a glass substrate 80, a pixel unit 83, a drive circuit unit 96, and the protection circuit unit 97.

On the glass substrate 80, a plurality pieces of gate wiring (scanning wiring) 81 and a plurality of pieces of source wiring (signal wiring) 82 intersect to form the pixel unit 83. Further, the glass substrate 80 is provided with the pixel unit 83 that displays an image, and a frame region 84 provided so as to surround the pixel unit 83. In the frame region 84, a scanning line drive circuit 95, a signal line drive circuit 94, and the protection circuit unit 97 are configured. The scanning line drive circuit 95 and the signal line drive circuit 94 are respectively connected to the gate wiring 81 and the source wiring 82.

The pixel unit 83 is configured with a plurality of pixels 85 arranged in a matrix. The pixel 85 is configured by: a pixel transistor 86 connected to the gate wiring 81 and the source wiring 82; a holding capacitor unit 87; and a pixel electrode 88. The pixel configuration exemplified here shows a case where the holding capacitor unit 87 has one electrode connected to the pixel transistor 86 and another electrode connected to storage capacitor wiring 89. Further, the pixel electrode 88 configures one electrode that drives a display element (liquid crystal element).

The scanning line drive circuit 95 and the signal line drive circuit 94 drive the pixel transistor 86 of the pixel unit 83. Here, the scanning line drive circuit 95 and the signal line drive circuit 94 configure the drive circuit unit 96.

In addition, each piece of the gate wiring 81 and each piece of the source wiring 82 are connected to short ring wiring 91 via a bidirectional diode 90, in order to suppress electrostatic breakdown of the pixel unit 83 during manufacturing. The bidirectional diode 90 and the short ring wiring 91 configures the protection circuit unit 97, and the protection circuit unit 97 is formed in the frame region 84.

Next, a configuration of the protection circuit unit 97 will be described. As illustrated in FIG. 39, for example, in a TFT array substrate using amorphous silicon, a diode can be configured by connecting a gate electrode and a source (drain) electrode of a TFT, which is a thin film transistor. The actual bidirectional diode 90 can be configured by connection as illustrated in FIG. 40.

The bidirectional diode 90 includes a diode 92 and a diode 93. A gate electrode and a drain electrode of the diode 92 are connected to the gate wiring 81, and a source electrode is connected to the short ring wiring 91. Further, a gate electrode and a drain electrode of the diode 93 are connected to the short ring wiring 91, and a source electrode is connected to the gate wiring 81. That is, the protection circuit unit 97 illustrated in FIG. 40 has a configuration in which, for the gate wiring 81, the two diodes 92 and 93 each connect the gate wiring 81 and the short ring wiring 91 with rectifying directions opposite to each other.

When the gate wiring 81 is positively or negatively charged with respect to the short ring wiring 91 due to static electricity or the like, a current flows in a direction to cancel the charge. For example, when the gate wiring 81 is positively charged, a current flows in a direction in which the positive charge is released to the short ring wiring 91. This operation can suppress electrostatic breakdown or shift of a threshold voltage of the pixel transistor 86 connected to the charged gate wiring 81. In addition, dielectric breakdown of the insulating film can be suppressed between the charged gate wiring 81 and another wiring intersecting with the insulating layer.

Here, the diodes 92 and 93 of the protection circuit unit 97 require a high resistance value to some extent. In order to drive a display apparatus, a voltage of 20 V or more to 30 V or less is usually required. When a current flows through the diodes 92 and 93 at a voltage that is normally applied, a desired voltage is not applied to the pixel, and display abnormality occurs. In order to suppress such problems, it is necessary to increase a diode resistance by increasing a channel length or decreasing a channel width.

In a case of a conventional diode using amorphous silicon, the amorphous silicon film itself has high resistance. Therefore, by individually setting a channel length and a channel width of the diode to about 5 μm or more and 10 μm or less, it is possible to obtain a diode resistance that does not particularly cause a problem in display. However, in recent years, TFTs using an oxide semiconductor have been used in place of the conventionally used amorphous silicon TFTs, in order to achieve higher definition and a built-in drive circuit unit. Oxide semiconductors are expected as next-generation materials with high mobility. As an oxide semiconductor, there are a zinc oxide (ZnO)-based material, an amorphous InGaZnO-based material in which gallium oxide (Ga₂O₃) and indium oxide (In₂O₃) are added to zinc oxide, and the like.

Since oxide semiconductors have about two orders higher mobility and higher carrier concentration than amorphous silicon films, a diode resistance of diodes using oxide semiconductors is two or three orders lower than that using amorphous silicon. In order to increase the diode resistance, it is necessary to increase the channel length, and in order to obtain a desired resistance value, it is necessary to increase the channel length to several tens μm or more to 100 μm or less. Increasing the channel length leads to enlargement of the diode element, which accordingly increases an area of a frame region, making it difficult to narrow the frame region. The following preferred embodiments solve such a problem.

### First Preferred Embodiment

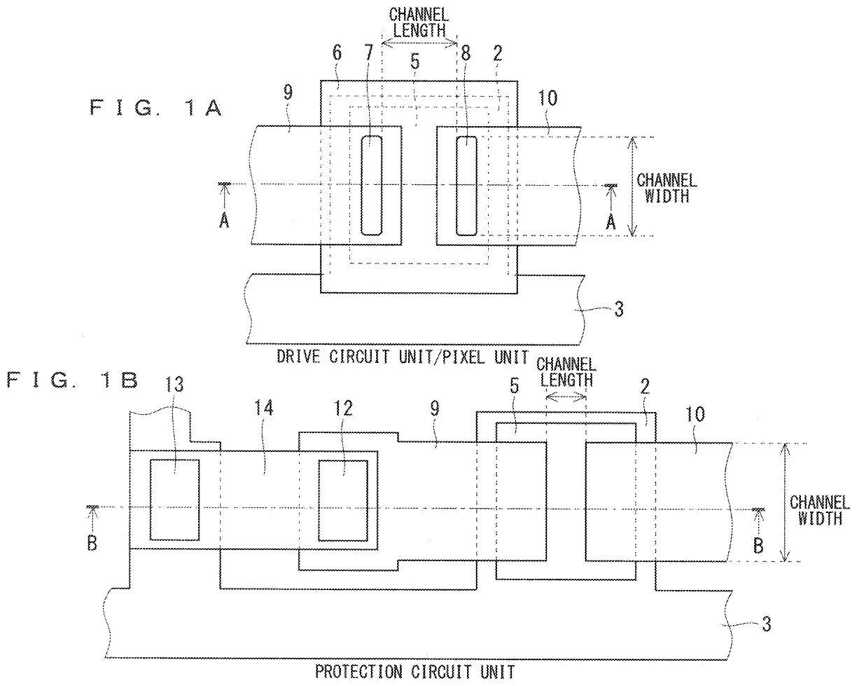

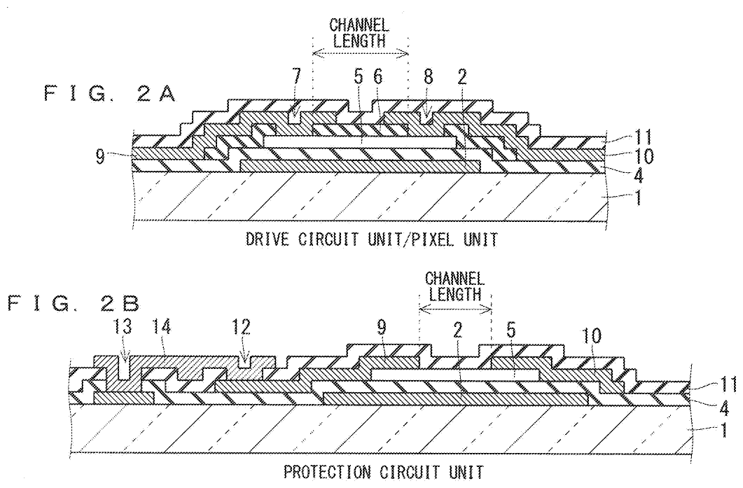

A first preferred embodiment of the present invention will be described below with reference to the drawings. FIG. 1A is a plan view of a drive circuit unit and a pixel unit included in a TFT array substrate according to the first preferred embodiment. FIG. 1B is a plan view of a protection circuit unit included in the TFT array substrate. FIG. 2A is a cross-sectional view of the drive circuit unit and the pixel unit included in the TFT array substrate according to the first preferred embodiment, and specifically is a cross-sectional view taken along line A-A in FIG. 1A. FIG. 2B is a cross-sectional view of the protection circuit unit included in the TFT array substrate according to the first preferred embodiment, and specifically is a cross-sectional view taken along line B-B of FIG. 1B. In the plan view of FIGS. 1A and 1B, illustration of a glass substrate 1 is omitted in order to make the drawings easily viewable, and the same applies to the following plan views.

In a structure of the TFT array substrate according to the first preferred embodiment, differences from the related art will be described.

As illustrated in FIGS. 1A and 1B and FIGS. 2A and 2B, on the glass substrate 1, which is a transparent insulating substrate such as glass, for example, a gate electrode 2 and gate wiring 3 are formed by processing a first conductive film made of metal or the like. Next, a gate insulating layer 4 made of a first insulating film is formed so as to cover them. On the gate insulating layer 4, a channel layer 5 made of an oxide semiconductor film is formed so as to be overlapped with the gate electrode 2. Here, the channel layer 5 is disposed inside the gate electrode 2 in plan view.

Next, a channel protective layer 6 is formed so as to cover the channel layer 5 of the drive circuit unit and the pixel unit. In the channel protective layer 6, a first contact hole 7 and a second contact hole 8 reaching the channel layer 5 are opened so as to be disposed inside the channel layer 5 in plan view.

Next, on the channel layer 5 and the channel protective layer 6, a source electrode 9 and a drain electrode 10 made of a second conductive film are formed. In the protection circuit unit, the channel layer 5 between the source electrode 9 and the drain electrode 10 functions as a TFT channel. A channel length is a distance between the electrodes, and a channel width is a width of the electrodes. Note that the source electrode 9 and the drain electrode 10 included in the TFT of the protection circuit unit correspond to a second source electrode and a second drain electrode, respectively.

Further, in the drive circuit unit and the pixel unit, the source electrode 9 and the drain electrode 10 are electrically connected to the channel layer 5 through the first contact hole 7 and the second contact hole 8, and a portion between the first contact hole 7 and the second contact hole 8 functions as a channel. As illustrated in FIGS. 1A and 1B and FIGS. 2A and 2B, a channel length is a portion between the first contact hole 7 and the second contact hole 8, and a channel width is a contact hole width in a direction orthogonal to the channel length. Note that the source electrode 9 and the drain electrode 10 included in the TFT of the drive circuit unit and the pixel unit correspond to a first source electrode and a first drain electrode, respectively.

Next, a protective insulating layer 11 is formed so as to cover the entire glass substrate 1. In the protective insulating layer 11, a third contact hole 12 and a fourth contact hole 13 reaching the gate wiring 3 and the source electrode 9 (or the drain electrode 10) are opened.

Next, on the protective insulating layer 11, connection wiring 14 made of a third conductive film is formed. The connection wiring 14 is electrically connected to the source electrode 9 and the gate wiring 3 through the third contact hole 12 and the fourth contact hole 13, respectively. Although not shown here, a contact hole is formed in the protective insulating layer 11 so as to be placed on the drain electrode 10 in the pixel unit, and a pixel electrode made of the third conductive film is electrically connected to the drain electrode 10 through the contact hole.

In the first preferred embodiment, as the oxide semiconductor film, for example, it is possible to use a ZnO-based oxide semiconductor film, an InZnSnO-based oxide semiconductor film or zinc oxide (ZnO)-based oxide semiconductor film in which indium oxide (In₂O₃) and tin oxide (SnO₂) are added to zinc oxide (ZnO), an InGaZnO-based oxide semiconductor film in which gallium oxide (Ga₂O₃) and indium oxide (In₂O₃) are added to zinc oxide (ZnO), or the like. A carrier concentration of the oxide semiconductor film is desirably adjusted to be about 1E+12/cm³ or more and about 1E+15/cm³ or less.

Next, an application example of the TFT array substrate according to the first preferred embodiment to a liquid crystal display will be described. However, the configuration other than the TFT array substrate will be briefly described because it is possible to combine a configuration of a generally known liquid crystal display. A liquid crystal display including the TFT array substrate according to the first preferred embodiment includes a TFT array substrate and a counter substrate arranged to face the TFT array substrate.

The TFT array substrate and the counter substrate are bonded to each other with a certain gap (cell gap). Then, a liquid crystal layer is disposed in the gap. That is, the TFT array substrate and the counter substrate are arranged to face each other with the liquid crystal layer interposed in between. Further, on outer surfaces of the TFT array substrate and the counter substrate, a polarizing plate is provided. Instead of the polarizing plate, a retardation plate or the like may be provided. Further, on a side opposite to a viewing side of the liquid crystal display configured as described above, there is disposed a backlight unit and the like including optical members such as a light source and a light guide plate.

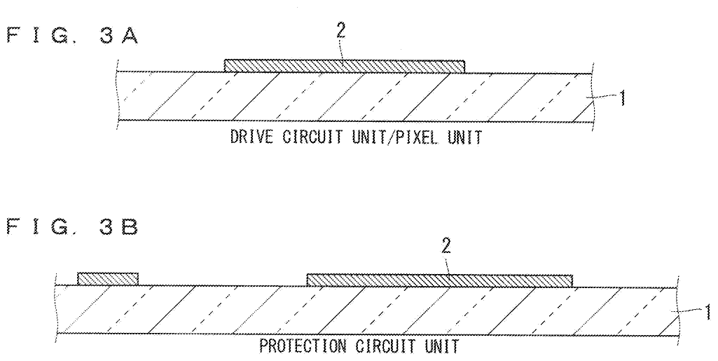

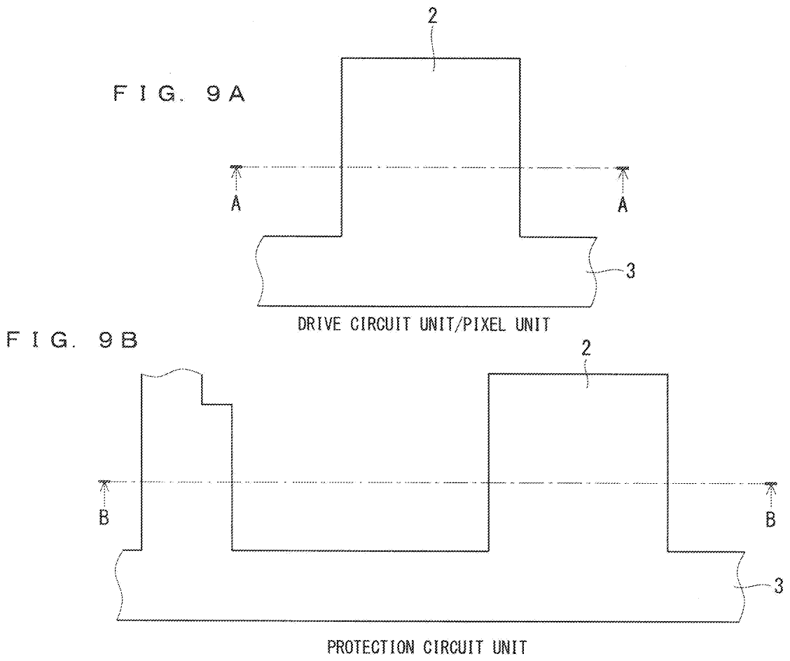

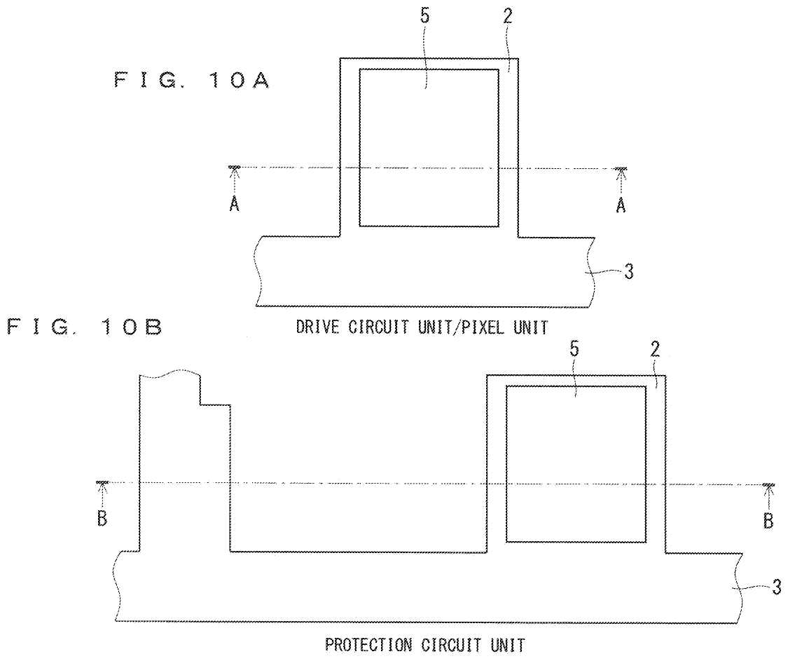

Next, a manufacturing method of the TFT array substrate according to the first preferred embodiment will be described with reference to FIGS. 3A and 3B to 14A and 14B. FIGS. 3A and 3B to FIGS. 8A and 8B are cross-sectional views each illustrating a manufacturing process of a TFT array substrate. FIGS. 9A and 9B to FIGS. 14A and 14B are plan views each illustrating a manufacturing process of a TFT array substrate. Note that FIGS. 3A to 14A are views related to the drive circuit unit and the pixel unit, and FIGS. 3B to 14B are views related to the protection circuit unit. Further, FIGS. 3A to 8A are cross-sectional views taken along line A-A in FIGS. 9A to 14A, respectively, and FIGS. 3B to 8B are cross-sectional views taken along line B-B in FIGS. 9B to 14B, respectively.

First, a first conductive film is formed on the glass substrate 1, which is a transparent insulating substrate such as glass. Here, an AL alloy (e.g., AL-Ni—Nd) film is formed as the first conductive film by a DC magnetron sputtering method to a thickness of 200 nm or more to 300 nm or less. Thereafter, a resist material is applied onto the AL alloy film, a photoresist pattern is formed in a first photoengraving process, and the AL alloy film is patterned by etching using the photoresist pattern as a mask.

As a result, the gate electrode 2 and the gate wiring 3 are formed on the glass substrate 1 as illustrated in FIGS. 3A and 3B and FIGS. 9A and 9B. Although the AL-Ni—Nd alloy is used here, other materials can be used as long as the wiring resistance is sufficiently low. Since the AL-Ni—Nd alloy of the first preferred embodiment is mainly composed of AL, the AL-Ni—Nd alloy has high conductivity, and is a material that can also be electrically connected to a transparent conductive film such as ITO, by the added Ni. For etching of the AL alloy, generally known PAN-based etchant (mixed acid of phosphoric acid, nitric acid, and acetic acid) has been used.

Next, the gate insulating layer 4 as a first insulating layer is formed on the entire top surface of the glass substrate 1. In the first preferred embodiment, a silicon nitride film (SiN) of 400 nm and a silicon oxide film (SiO) of 50 nm have been sequentially formed using a chemical vapor deposition (CVD) method. Note that the silicon oxide film has a weak barrier property against impurity elements that affect the TFT characteristics, such as moisture (H₂O), hydrogen (H₂), sodium (Na), and potassium (K). Therefore, a laminated structure is adopted in which a SiN film having an excellent barrier property is provided below the SiO film.

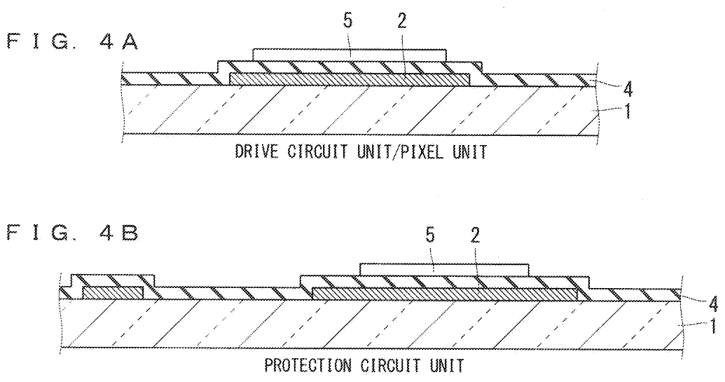

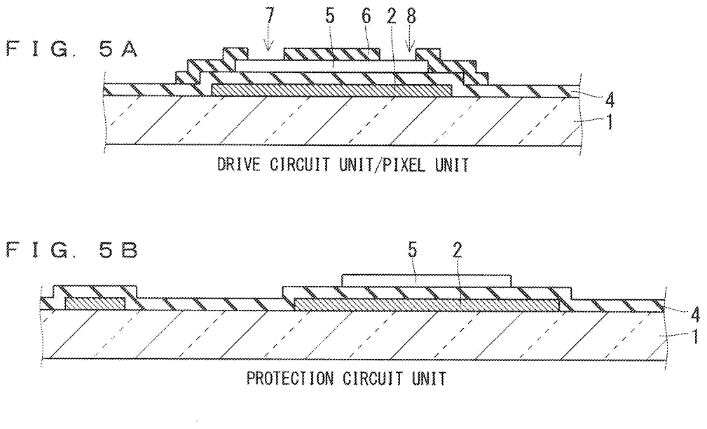

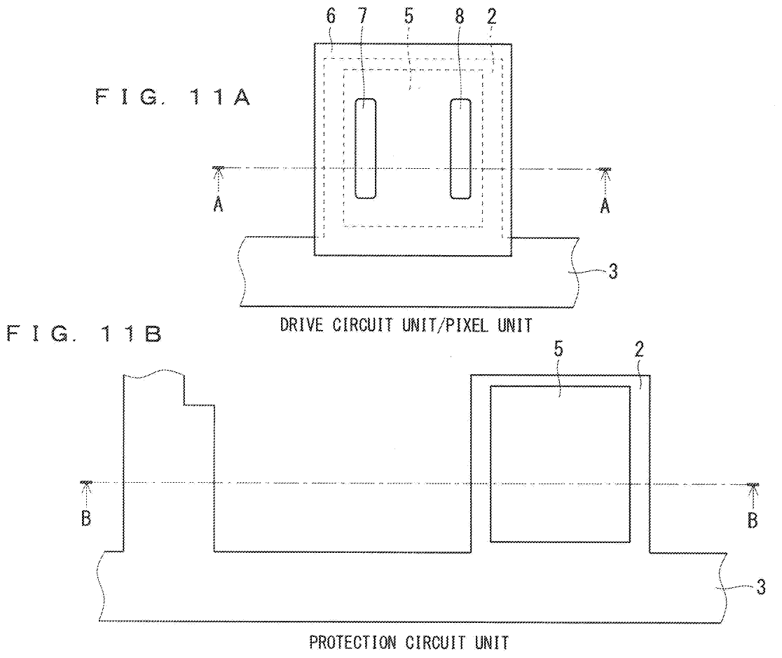

Thereafter, as illustrated in FIGS. 4A and 4B and FIGS. 10A and 10B, the channel layer 5 made of an oxide semiconductor film is formed on the gate insulating layer 4. In the first preferred embodiment, an In—Zn—Sn—O target [In₂O₃(ZnO)₆.(SnO₂)₂] having an atomic composition ratio In:Zn:Sn:O of 2:6:2:13 is used, and the film has been formed to a thickness of 50 nm by the DC magnetron method. At this time, in a case of performing sputtering using a known Ar gas, an oxide film is usually to be in an oxygen ion deficient state in which an atomic composition ratio of oxygen is smaller than a stoichiometric composition (in the above example, the composition ratio of 0 is less than 13).

Therefore, it is desirable to mix oxygen gas with Ar gas for sputtering. Here, sputtering has been performed using a mixed gas in which O₂ gas having a partial pressure ratio of 5% or more to 20% or less is added to Ar gas. The In—Zn—Sn—O film immediately after the film formation has an amorphous structure, and is soluble in chemical liquid containing oxalic acid. Whereas, with PAN chemical liquid, film loss is hardly observed even after immersion for 5 minutes within a range of a liquid temperature of 20° C. to 40° C., and etching processing is not possible.

Next, a photoresist pattern is formed in a second photoengraving process, and the oxide semiconductor is etched using the photoresist pattern as a mask. For the etching, wet etching using chemical liquid containing oxalic acid can be used. The chemical liquid desirably contains oxalic acid in a range of 1 wt % or more to 10 wt % or less. In the first preferred embodiment, the oxide semiconductor has been etched using oxalic acid-based chemical liquid of oxalic acid 5 wt %+water. Then, the photoresist pattern is removed, and the entire glass substrate 1 has been subjected to an annealing process in an air atmosphere at 350° C. for 60 minutes such that a carrier concentration of the oxide semiconductor is about 1E+12/cm³ or more to 1E+15/cm³ or less.

By performing the annealing process including oxygen, oxygen can be further supplied to the oxide semiconductor film, and the carrier concentration can be adjusted. Further, since structural relaxation also simultaneously occurs, structural defects are reduced and a high quality semiconductor film is obtained. Here, an air atmosphere is used, but a water vapor atmosphere may be used. Alternatively, an atmosphere may be used in which oxygen gas and nitrogen gas are mixed from a gas cylinder at a certain ratio. Ozone having high oxidizing power may be generated with irradiation of UV light during the annealing process.

Next, a second insulating layer is formed so as to cover the channel layer 5 of the drive circuit unit and of the pixel unit on the glass substrate 1. In the first preferred embodiment, a silicon oxide film (SiO) of 50 nm is formed using the chemical vapor deposition (CVD) method. By forming the SiO film containing 0 atoms, it is possible to suppress reduction of the oxide semiconductor film at an interface between with the oxide semiconductor film below. Moreover, it is possible to protect from an influence by each process, such as plasma damage in a post process.

Next, a photoresist pattern is formed in a third photoengraving process, and the second insulating layer is etched using the photoresist pattern as a mask. For this etching, a dry etching method using a gas containing fluorine (F) can be used. Here, etching is performed using a dry etching method using a gas obtained by adding oxygen (O₂) to sulfur hexafluoride (SF₆).

After the etching, as illustrated in FIGS. 5A and 5B and FIGS. 11A and 11B, a channel protective layer 6 is formed on the channel layer 5 in the drive circuit unit and the pixel unit. At this time, in the channel protective layer 6, the first contact hole 7 and the second contact hole 8 are opened inside the channel layer 5 in plan view.

Next, Mo alloy, chromium, AL alloy (e.g., AL-Ni—Nd), or the like is formed as the second conductive film by the DC magnetron sputtering method. In the first preferred embodiment, a laminated structure is adopted in which films of MoNb alloy and AL-Ni—Nd alloy are sequentially and individually formed with a thickness of 100 nm. Next, a photoresist pattern is formed in a fourth photoengraving process, and the laminated film of the AL alloy and the Mo alloy is etched using the photoresist pattern as a mask.

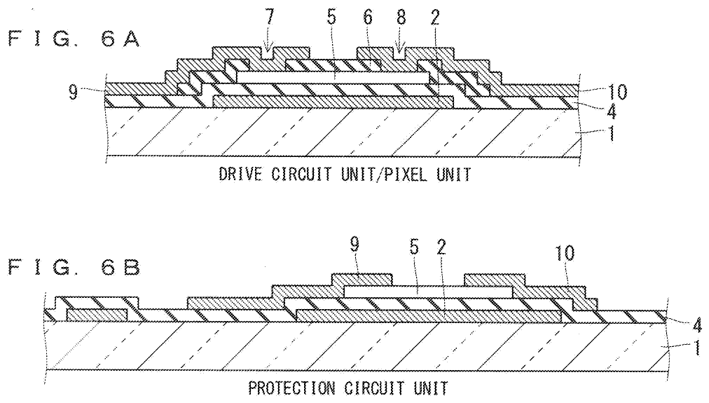

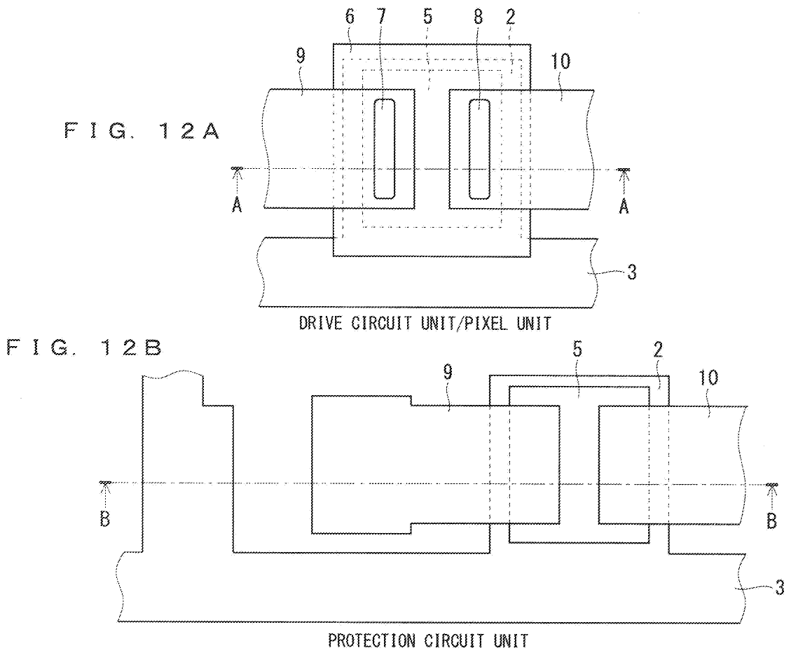

By this etching, as illustrated in FIGS. 6A and 6B and FIGS. 12A and 12B, the source electrode 9 and the drain electrode 10 are formed on the channel layer 5 and the channel protective layer 6. For the etching, a wet etching method using a solution (PAN chemical liquid) containing phosphoric acid, acetic acid, and nitric acid can be used. Here, etching has been performed using PAN chemical liquid of phosphoric acid 70 wt %+acetic acid 7 wt %+nitric acid 5 wt %+water. Thereafter, the photoresist pattern is removed, and oxidation treatment is performed.

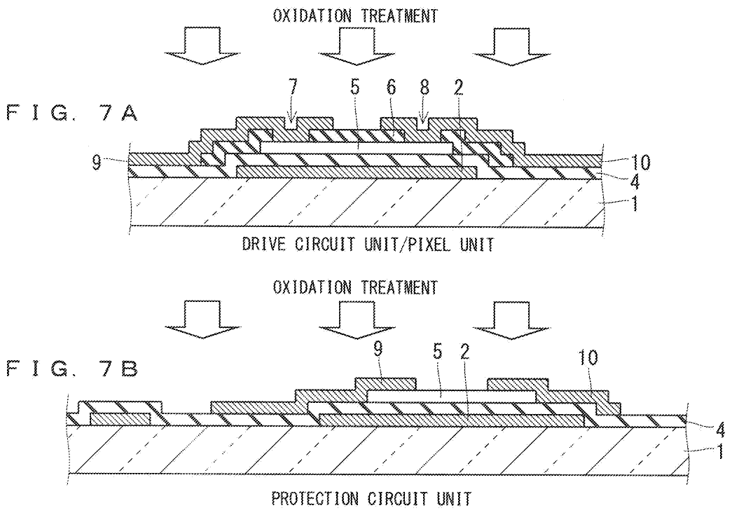

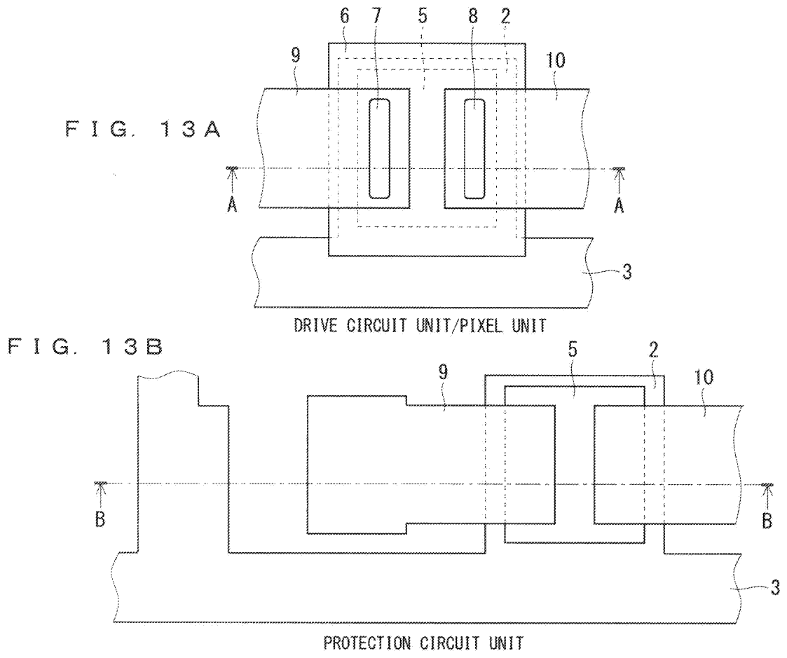

As illustrated in FIGS. 7A and 7B and FIGS. 13A and 13B, in the channel layer 5 of the protection circuit unit, oxidation has been performed such that a carrier concentration in a channel portion not covered with the source electrode 9 and the drain electrode 10 is 1E+10/cm³ or less. In the channel layer 5 of the drive circuit unit and the pixel unit, the carrier concentration hardly decreases but remains 1E+12/cm³ to 1E+15/cm³ since the channel protective layer 6 protects against oxidation treatment.

In this oxidation treatment, plasma treatment using N₂O gas has been performed for 60 seconds or more to 180 seconds or less. N₂O gas may be mixed with rare gas such as argon or helium, and O₂ gas or ozone may be used other than N₂O gas. This oxidation treatment increases an oxygen ratio of an oxide semiconductor channel in the protection circuit unit as compared with an oxygen ratio of an oxide semiconductor channel in the drive circuit unit and the pixel unit.

Next, the protective insulating layer 11 as a third insulating film is formed so as to cover the entire glass substrate 1. In the first preferred embodiment, by using the chemical vapor deposition (CVD) method, a silicon oxide film (SiO) has been first formed to a thickness of 200 nm, and then silicon nitride (SiN) has been subsequently formed to a thickness of 150 nm.

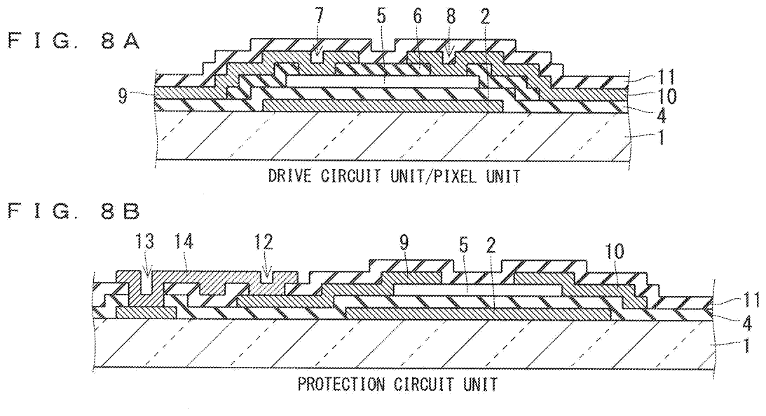

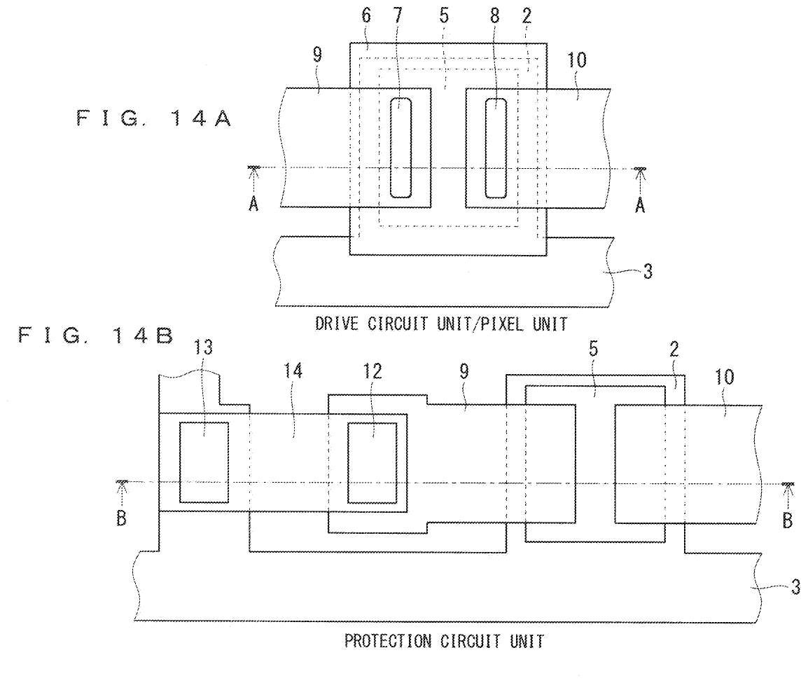

Then, a photoresist pattern is formed in a fifth photoengraving process, and the protective insulating layer 11 is etched using the photoresist pattern as a mask. Here, etching is performed using a dry etching method using a gas obtained by adding oxygen (O₂) to sulfur hexafluoride (SF₆), and the third contact hole 12 and the fourth contact hole 13 are formed as illustrated in FIGS. 8A and 8B and FIGS. 14A and 14B. Further, in a pixel region, a contact hole (not shown) is formed in the protective insulating layer 11 at a position placed on the drain electrode 10.

Next, a third conductive film is formed. In the first preferred embodiment, an amorphous ITO film, which is a transparent conductive film, is formed with a thickness of 50 nm or more to 80 nm or less by the DC magnetron method. As the sputtering gas, Ar mixed with water vapor has been used.

Thereafter, a photoresist pattern is formed in a sixth photoengraving process, and the amorphous ITO film is etched using the photoresist pattern as a mask. The etching has been performed by a wet etching method using oxalic acid-based chemical liquid of oxalic acid 5 wt %+water.

Thereafter, the photoresist pattern is removed, and the connection wiring 14 is formed as illustrated in FIGS. 8A and 8B and FIGS. 14A and 14B. The connection wiring 14 is electrically connected to the source electrode 9 and the gate wiring 3 through the third contact hole 12 and the fourth contact hole 13, respectively. At this time, although not shown here, a pixel electrode is formed in the pixel unit, and is electrically connected to the drain electrode 10 through a contact hole opened in the protective insulating layer 11 at a position placed on the drain electrode 10 described above.

Thereafter, in order to eliminate plasma damage and the like generated on the TFT array substrate during the manufacturing process, heat treatment is performed in an air atmosphere at a temperature of 230° C. for 60 minutes, to complete the TFT array substrate.

When the liquid crystal display panel is assembled, an alignment film and a spacer are formed on a surface of the completed TFT array substrate. The alignment film is a film for aligning liquid crystals, and is formed of polyimide or the like. In addition, a counter substrate provided with a color filter and an alignment film and separately produced is bonded to the TFT substrate manufactured by the above method. At this time, a gap is formed between the TFT substrate and the counter substrate by the spacer, and a liquid crystal layer is formed and sealed in the gap to form a liquid crystal display panel. Finally, a liquid crystal display is completed by disposing a polarizing plate, a retardation plate, a backlight unit, and the like outside the liquid crystal display panel.

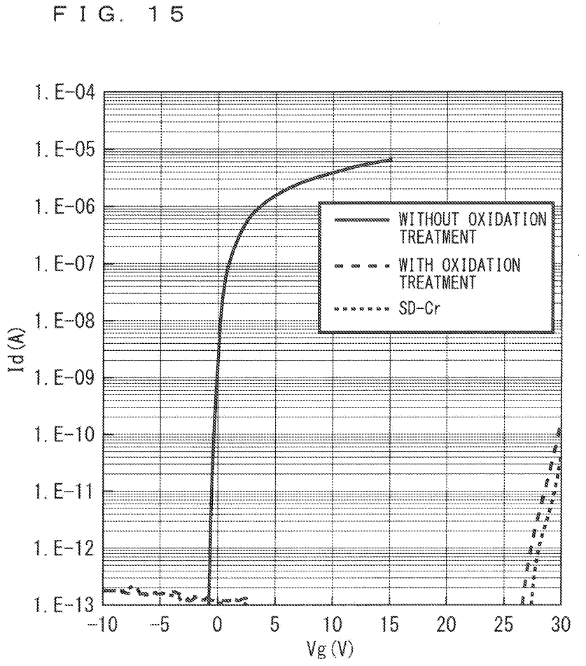

FIG. 15 is a graph showing an Id-Vg curve of a TFT of the protection circuit unit included in the TFT array substrate according to the first preferred embodiment. As shown in FIG. 15, it can be seen that, when the oxidation treatment is performed and when Cr is used for the source and drain electrodes, a current between the source and the drain is required to increase a gate voltage to 27 V or higher, and the resistance is high. As described above, in the TFT array substrate according to the first preferred embodiment, the TFT included in the protection circuit unit does not include the channel protective layer 6. Therefore, a carrier concentration of the channel layer 5 in the protection circuit unit can be made lower than a carrier concentration of the channel layer 5 in the pixel unit and the drive circuit unit, for example, by performing oxidation treatment after the formation of the source electrode 9 and the drain electrode 10. This can increase the diode resistance when the TFT included in the protection circuit unit is diode-connected, enabling reduction of the channel length. As a result, an occupied area of the protection circuit unit is reduced, and the frame can be narrowed.

In the TFT of the drive circuit unit and the pixel unit, the channel protective layer 6 is disposed on the channel layer 5, and therefore the channel layer 5 is not subjected to process damage of the post process. Therefore, the performance and reliability of the TFT can be improved.

Since a metal composition of the channel layer 5 in the pixel unit and the drive circuit unit is same as a metal composition of the channel layer 5 in the protection circuit unit, the channel layer 5 in the pixel unit, the drive circuit unit, and the protection circuit unit can be formed in a same process. This can suppress complication of the manufacturing method of the TFT array substrate.

An oxygen ratio of the channel layer 5 in the pixel unit and the drive circuit unit is lower than an oxygen ratio of the channel layer 5 in the protection circuit unit. That is, since the oxygen ratio of the channel layer 5 in the protection circuit unit is higher than the oxygen ratio of the channel layer 5 in the pixel unit and the drive circuit unit, the diode resistance of the protection circuit unit can be increased.

A carrier concentration of the channel layer 5 in the pixel unit and the drive circuit unit is higher than a carrier concentration of the channel layer 5 in the protection circuit unit. That is, since the carrier concentration of the channel layer 5 in the protection circuit unit is lower than the carrier concentration of the channel layer 5 in the pixel unit and the drive circuit unit, the diode resistance of the protection circuit unit can be increased.

Note that, in the first preferred embodiment, it has been described that the second conductive film is made of the laminated film of MoNb alloy and AL-Ni—Nd alloy, but the present invention is not limited to this. The second conductive film may be made of a single layer film or a laminated film formed of a plurality of layers using Cr, Cu, Mo, or an alloy containing one of these. This allows formation of the source electrode 9 and the drain electrode 10 made of the second conductive film by various methods.

Furthermore, for etching these metals, it is desirable to use a CAN-based etching solution containing ceric ammonium nitrate. Since the channel layer 5 is oxidized when exposed to the CAN-based etching solution, a channel region of the channel layer 5 of the protection circuit unit can be simultaneously oxidized when the source electrode 9 and the drain electrode 10 are formed. Since oxidation can be performed at the same time as the formation of the electrode, an additional oxidation treatment process is not required and productivity is improved.

### Second Preferred Embodiment

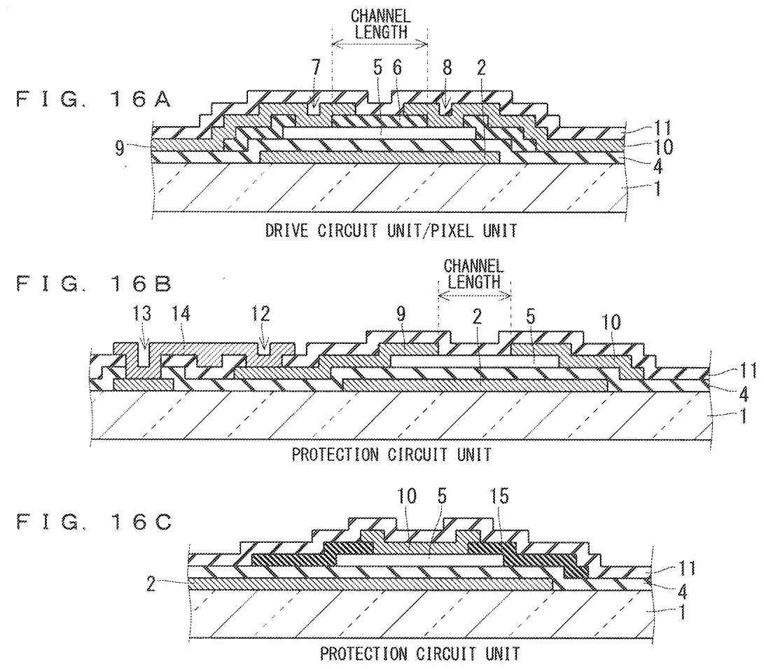

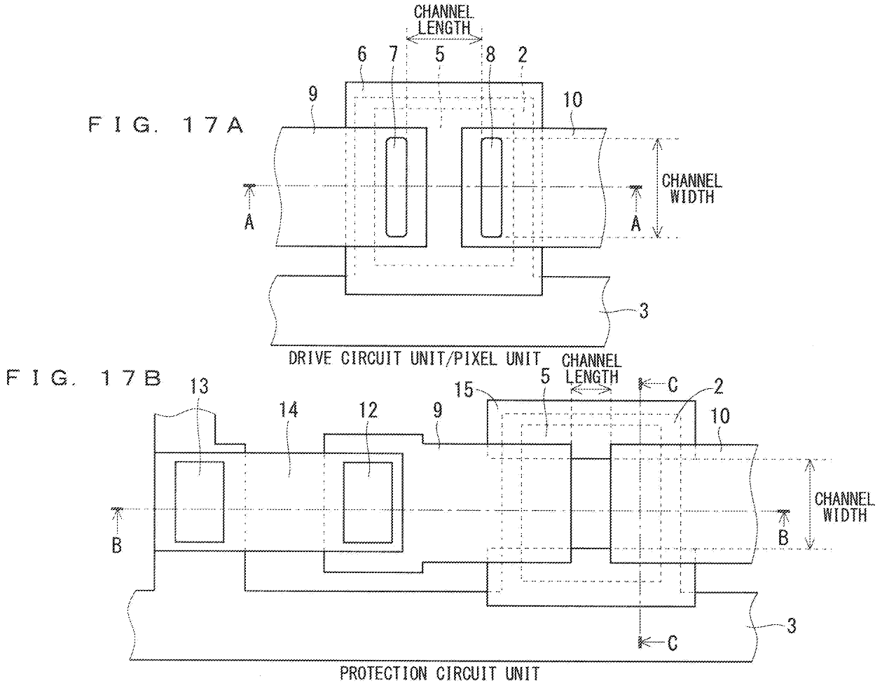

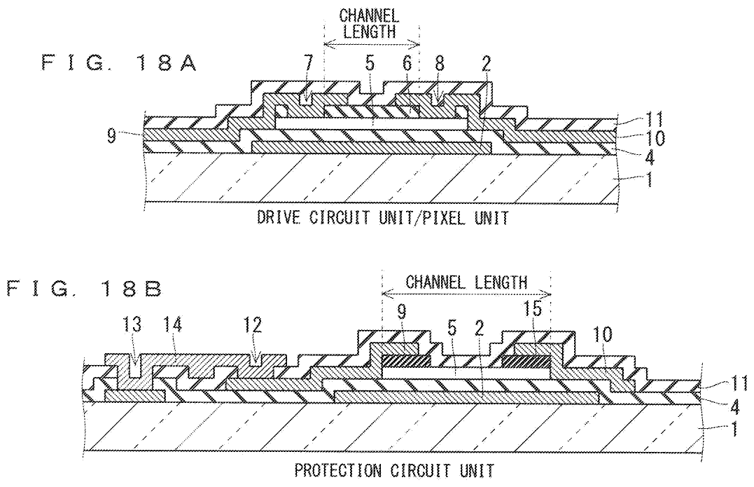

Next, a TFT array substrate according to a second preferred embodiment will be described. FIG. 16A is a cross-sectional view of a drive circuit unit and a pixel unit included in the TFT array substrate according to the second preferred embodiment. FIGS. 16B and 16C are cross-sectional views of a protection circuit unit included in the TFT array substrate according to the second preferred embodiment. FIG. 17A is a plan view of the drive circuit unit and the pixel unit included in the TFT array substrate according to the second preferred embodiment. FIG. 17B is a plan view of the protection circuit unit included in the TFT array substrate according to the second preferred embodiment. Here, FIG. 16A is a cross-sectional view taken along line A-A of FIG. 17A. FIG. 16B is a cross-sectional view taken along line B-B of FIG. 17B. FIG. 16C is a cross-sectional view taken along line C-C of FIG. 17B. Note that, in the second preferred embodiment, the same constituent elements as those described in the first preferred embodiment are denoted by the same reference numerals, and a description thereof will be omitted.

As illustrated in FIGS. 16A to 16C and FIGS. 17A and 17B, on a glass substrate 1, for example, a gate electrode 2 and gate wiring 3 are formed by processing a first conductive film made of metal or the like, similarly to a case of the first preferred embodiment.

Next, a gate insulating layer 4 made of a first insulating film is formed so as to cover them. On the gate insulating layer 4, a channel layer 5 made of an oxide semiconductor film is formed so as to be overlapped with the gate electrode 2. Here, the channel layer 5 is disposed inside the gate electrode 2 in plan view.

Next, a second insulating layer is formed on the channel layer 5. Here, in the drive circuit unit and the pixel unit, the second insulating layer serves as a channel protective layer 6 covering the channel layer 5 except for a contact hole described later. In the protection circuit unit, the second insulating layer serves as a protective layer 15 covering a part of a top surface of the channel layer 5 and a side surface portion of the channel layer 5, in a channel direction.

In the drive circuit unit and the pixel unit, in the second insulating layer, the first contact hole 7 and the second contact hole 8 reaching the channel layer 5 are opened so as to be disposed inside the channel layer 5 in plan view.

Next, the source electrode 9 and the drain electrode 10 made of the second conductive film are formed on the channel layer 5 and the second insulating layer. In the drive circuit unit and the pixel unit, the source electrode 9 and the drain electrode 10 are electrically connected to the channel layer 5 through the first contact hole 7 and the second contact hole 8. In this case, a portion between the first contact hole 7 and the second contact hole 8 functions as a channel. As illustrated in FIGS. 16A and 17A, a channel length is a portion between the first contact hole 7 and the second contact hole 8, and a channel width is a contact hole width in a direction orthogonal to the channel hole length.

As illustrated in FIGS. 16B and 17B, in the protection circuit unit, the channel layer 5 between the source electrode 9 and the drain electrode 10 functions as a TFT channel. A channel length is a distance between the source electrode 9 and the drain electrode 10, and a channel width is a distance between the protective layers 15 segmented into two.

Next, a protective insulating layer 11 made of a third insulating layer is formed so as to cover the entire glass substrate 1. In the protective insulating layer 11, a third contact hole 12 and a fourth contact hole 13 respectively reaching the source electrode 9 (or the drain electrode 10) and the gate wiring 3 are opened.

Next, on the protective insulating layer 11, connection wiring 14 made of a third conductive film is formed. The connection wiring 14 is electrically connected to the source electrode 9 and the gate wiring 3 through the third contact hole 12 and the fourth contact hole 13, respectively. Although not shown here, a contact hole is formed in the protective insulating layer 11 so as to be placed on the drain electrode 10 in the pixel unit, and a pixel electrode made of the third conductive film is electrically connected to the drain electrode 10 through the contact hole.

In the second preferred embodiment, in the protection circuit unit, a side surface portion in a channel direction of the channel layer 5 is covered with the protective layer 15. This can suppress defects that occur in the side surface portion of the channel layer 5. The side surface portion of the channel layer 5 tends to be tapered by a wet etching process, and a film thickness of an end portion gradually decreases toward the edge. The tapered portion tends to have defects due to process damage, and there is concern over increase in defects due to oxidation treatment that is performed to lower the carrier concentration. When a leak current is generated through the defects, the diode resistance decreases and the diode resistance varies, which causes a decrease in the yield of the TFT array substrate. The channel width is defined by a distance between the protective layers 15 as described above, but the vicinity of the edge of the channel layer 5 can also be a channel since the actual current flows with a spread.

Note that the manufacturing method of the TFT array substrate according to the second preferred embodiment is the same as that in the first preferred embodiment, and thus the description thereof is omitted.

As described above, in the TFT array substrate according to the second preferred embodiment, the TFT included in the protection circuit unit further includes the protective layer 15 that covers a part of the channel layer 5 and the side surface portion of the channel layer 5 in the channel direction. In this way, by covering the side surface portion of the channel layer 5 in the channel direction with the protective layer 15, occurrence of defects is suppressed, and the diode resistance can be controlled to be high and stable. As a result, the yield of the TFT array substrate is improved.

### Third Preferred Embodiment

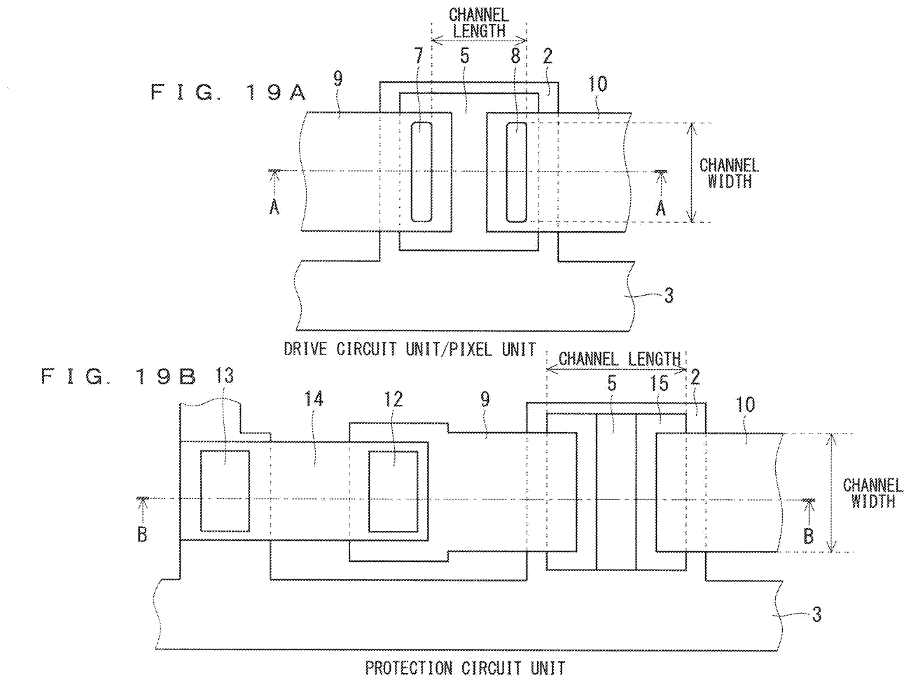

Next, a TFT array substrate according to a third preferred embodiment will be described. FIG. 18A is a cross-sectional view of a drive circuit unit and a pixel unit included in the TFT array substrate according to the third preferred embodiment. FIG. 18B is a cross-sectional view of a protection circuit unit included in the TFT array substrate according to the third preferred embodiment. FIG. 19A is a plan view of the drive circuit unit and the pixel unit included in the TFT array substrate according to the third preferred embodiment. FIG. 19B is a plan view of the protection circuit unit included in the TFT array substrate according to the third preferred embodiment. Here, FIG. 18A is a cross-sectional view taken along line A-A of FIG. 19A. FIG. 18B is a cross-sectional view taken along line B-B of FIG. 19B. Note that, in the third preferred embodiment, the same constituent elements as those described in the first and second preferred embodiments are denoted by the same reference numerals, and a description thereof will be omitted.

As illustrated in FIGS. 18A and 18B and FIGS. 19A and 19B, on a glass substrate 1, for example, a gate electrode 2 and gate wiring 3 are formed by processing a first conductive film made of metal or the like.

Next, a gate insulating layer 4 made of a first insulating film is formed so as to cover them. On the gate insulating layer 4, a channel layer 5 made of an oxide semiconductor film is formed so as to be overlapped with the gate electrode 2. Here, the channel layer 5 is disposed inside the gate electrode 2 in plan view.

Next, a second insulating layer is formed on the channel layer 5. Here, in the drive circuit unit and the pixel unit, a second insulating layer is formed so as to be overlapped with the channel layer 5 in plan view except for a contact hole, and serves as a channel protective layer 6. In the protection circuit unit, the second insulating layer serves as a protective layer 15 covering a part of a top surface of the channel layer 5.

In the drive circuit unit and the pixel unit, in the second insulating layer, a first contact hole 7 and a second contact hole 8 reaching the channel layer 5 are opened so as to be disposed inside the channel layer 5 in plan view.

Next, a source electrode 9 and a drain electrode 10 made of a second conductive film are formed on the channel layer 5 and the second insulating layer. In the drive circuit unit and the pixel unit, the source electrode 9 and the drain electrode 10 are electrically connected to the channel layer 5 through the first contact hole 7 and the second contact hole 8, respectively. In this case, a portion between the first contact hole 7 and the second contact hole 8 functions as a channel. As illustrated in FIG. 18A and FIG. 19A, a channel length is a portion between the first contact hole 7 and the second contact hole 8, and a channel width is a contact hole width in a direction orthogonal to the channel length.

In the protection circuit unit, the source electrode 9 and the drain electrode 10 are electrically connected to a side surface portion of the channel layer 5, and the channel layer 5 between the source electrode 9 and the drain electrode 10 functions as a TFT channel. As illustrated in FIGS. 18B and 19B, the channel length is the same as a width of the channel layer 5, and the channel width is the same as a width of the source electrode 9 and the drain electrode 10.

In the third preferred embodiment, the source electrode 9 and the drain electrode 10 are electrically connected exclusively to the side surface portion of the channel layer 5. Since a connection area of the source electrode 9 and the drain electrode 10 between with the channel layer 5 is reduced, the on-current of the diode can be reduced. This enables reduction of the channel length, making it possible to reduce an area of the protection circuit unit. Next, a protective insulating layer 11 made of a third insulating layer is formed so as to cover the entire glass substrate 1. Since the subsequent steps are the same as those in the first and second preferred embodiments, the description thereof is omitted.

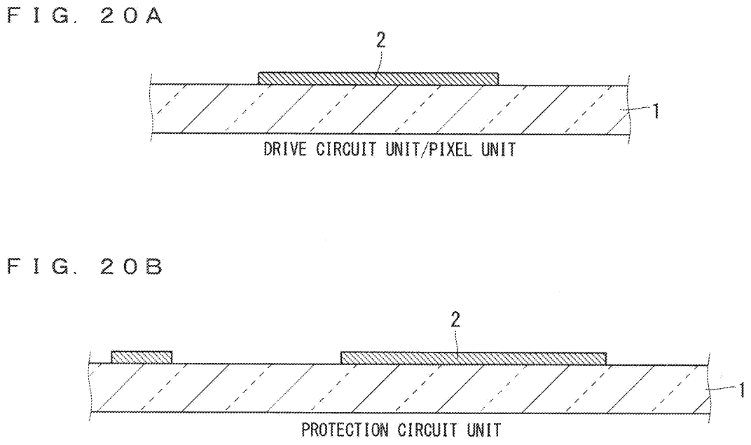

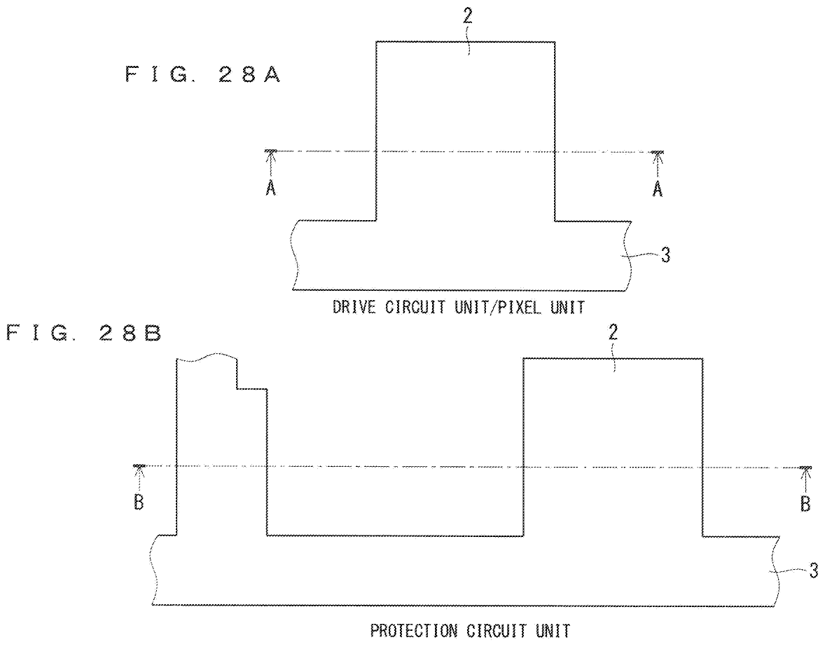

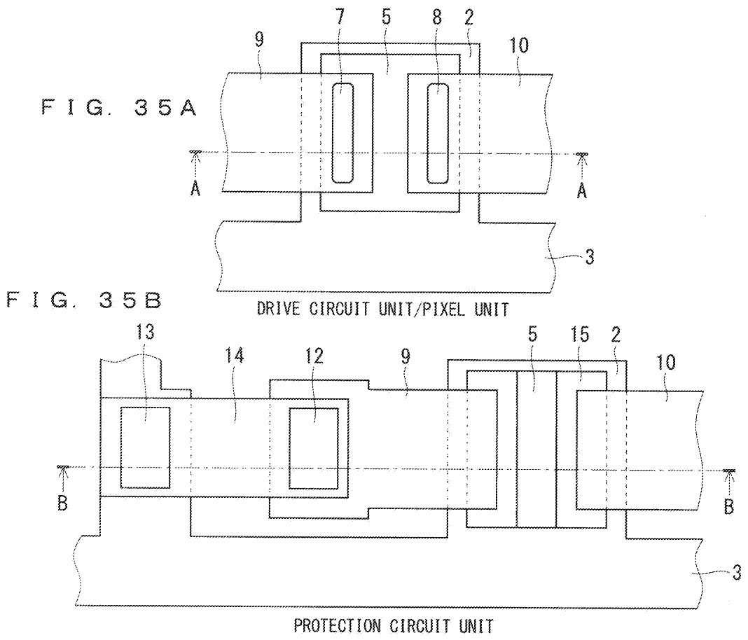

Next, a manufacturing method of the TFT array substrate according to the third preferred embodiment will be described with reference to FIGS. 20A and 20B to 35A and 35B. FIGS. 20A and 20B to 27A and 27B are cross-sectional views each illustrating a manufacturing process of the TFT array substrate. FIGS. 28A and 28B to 35A and 35B are plan views each illustrating a manufacturing process of the TFT array substrate. Note that FIGS. 20A to 35A are views related to the drive circuit unit and the pixel unit, and FIGS. 35B to 35B are views related to the protection circuit unit. Further, FIGS. 20A to 27A are cross-sectional views taken along line A-A in FIGS. 28A to 35A, respectively, and FIGS. 20B to 27B are cross-sectional views taken along line B-B in FIGS. 28B to 35B, respectively.

First, a first conductive film is formed on the glass substrate 1. Here, an AL alloy (e.g., AL-Ni—Nd) film is formed as the first conductive film by a DC magnetron sputtering method to a thickness of 200 nm or more to 300 nm or less. Thereafter, a resist material is applied onto the AL alloy film, a photoresist pattern is formed in a first photoengraving process, and the AL alloy film is patterned by etching using the photoresist pattern as a mask. As a result, the gate electrode 2 and the gate wiring 3 are formed on the glass substrate 1 as illustrated in FIGS. 20A and 20B and FIGS. 28A and 28B. Here, AL-Ni—Nd alloy has been used. For etching of the AL alloy, generally known PAN-based etchant (mixed acid of phosphoric acid, nitric acid, and acetic acid) has been used.

Next, the gate insulating layer 4 as a first insulating layer is formed on the entire top surface of the glass substrate 1. In the third preferred embodiment, a silicon nitride film (SiN) of 400 nm and a silicon oxide film (SiO) of 50 nm have been sequentially formed using a chemical vapor deposition (CVD) method.

Next, the channel layer 5 made of an oxide semiconductor film is formed on the gate insulating layer 4. In the third preferred embodiment, an In—Zn—Sn—O target [In₂O₃(ZnO)₆.(SnO₂)₂] having an atomic composition ratio In:Zn:Sn:O of 2:6:2:13 is used, and the film has been formed to a thickness of 50 nm by the DC magnetron method.

Next, a silicon oxide film (SiO) of 50 nm is formed as a second insulating layer on the channel layer 5, by using the chemical vapor deposition (CVD) method.

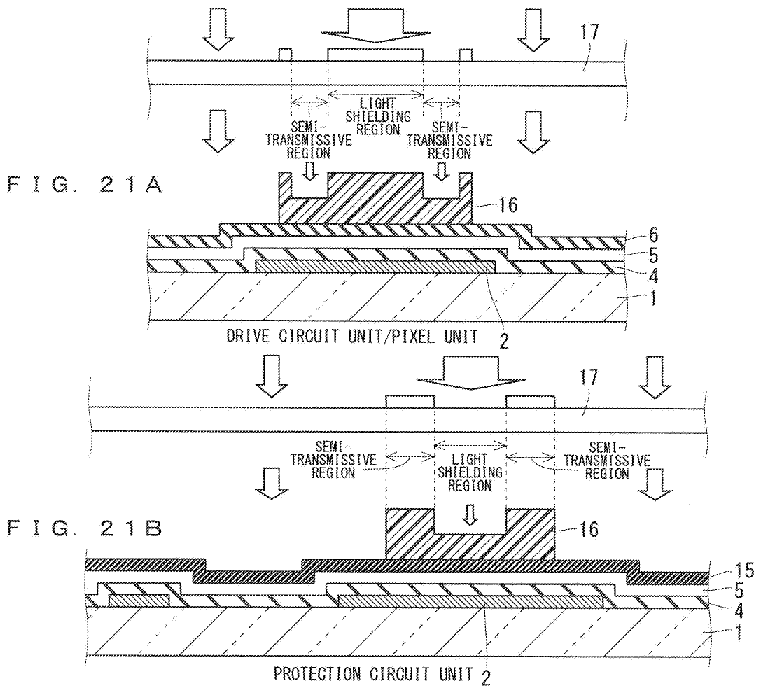

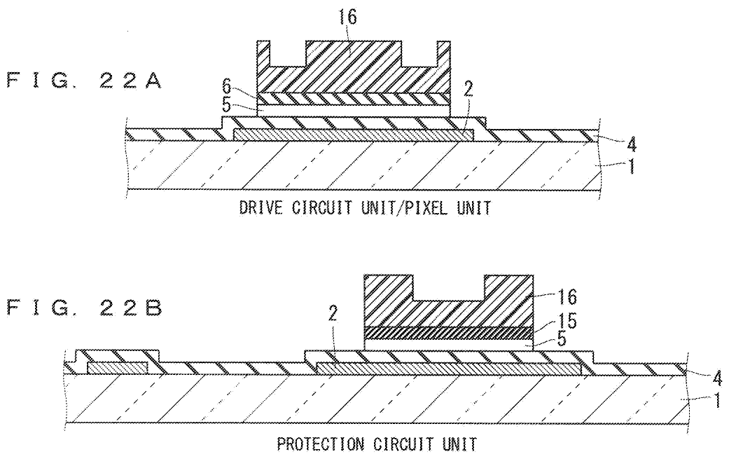

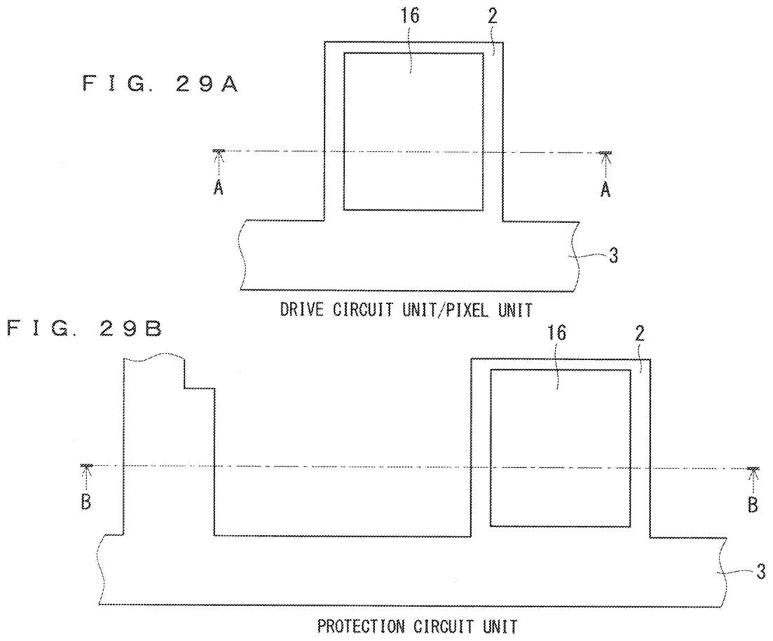

Next, the second insulating layer and the oxide semiconductor film are collectively patterned using a halftone mask in a second photoengraving process. First, as illustrated in FIGS. 21A and 21B and FIGS. 29A and 29B, on the second insulating layer, a photoresist 16 made of a novolac-based positive photosensitive resin is applied using a coating method to form a thickness of about 1.5 μm. Photoresist exposure is performed using a photomask 17 prepared in advance.

On the photomask 17, there is formed a light shielding film pattern for forming patterns of the channel layer 5, the channel protective layer 6, and the protective layer 15. A region where exposure light is blocked by the light shielding film pattern is a light shielding region. In addition, the photomask 17 is formed with a semi-transmissive pattern that reduces the light intensity of exposure in a portion that serves as a contact hole of the drive circuit unit and the pixel unit and a portion that serves as a channel of the protection circuit unit, and a region where the exposure light is attenuated by the semi-transmissive pattern becomes a semi-transmissive region.

After the photoresist 16 is exposed using the photomask 17, development is performed using an organic alkaline-based developer containing tetramethylammonium hydroxide (TMAH). This removes the photoresist except for portions corresponding to the channel layer 5 and the channel protective layer 6, as illustrated in FIGS. 21A and 21B and FIGS. 29A and 29B. At this time, in the portion serving as the contact hole of the drive circuit unit and the pixel unit and the portion corresponding to the channel of the protection circuit unit that have been exposed with the semi-transmissive photomask pattern, the photoresist remains with a film thickness thinner than that of the unexposed region. In the third preferred embodiment, the minimum film thickness is set to about 0.2 μm.

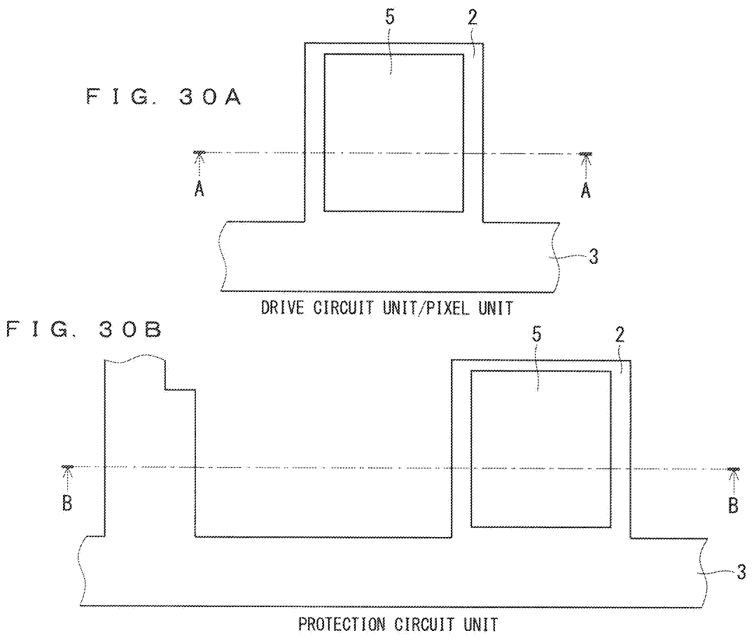

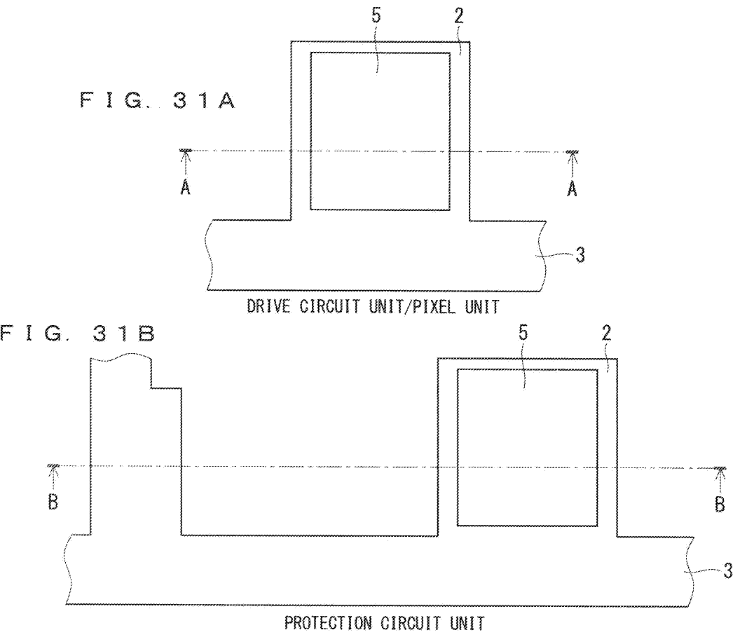

Subsequently, the second insulating layer is etched using a dry etching method using a gas obtained by adding oxygen (O₂) to sulfur hexafluoride (SF₆). Next, the oxide semiconductor film is etched with oxalic acid with the same resist pattern. As a result, as illustrated in FIGS. 22A and 22B and FIGS. 30A and 30B, the channel layer 5 and the channel protective layer 6 have a same area in plan view, or the channel layer 5 has a slightly smaller area than that of the channel protective layer 6. The reason why the area of the channel layer 5 is slightly smaller is due to an influence of side etching during the wet etching with oxalic acid.

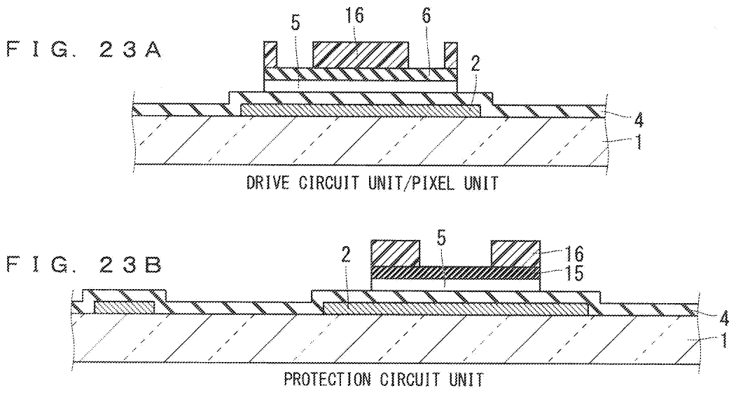

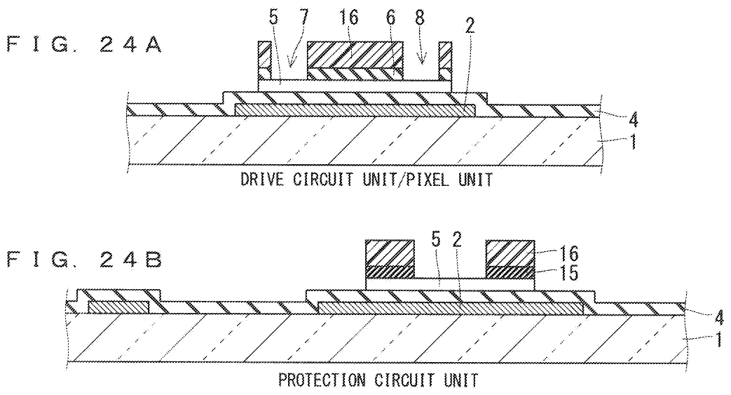

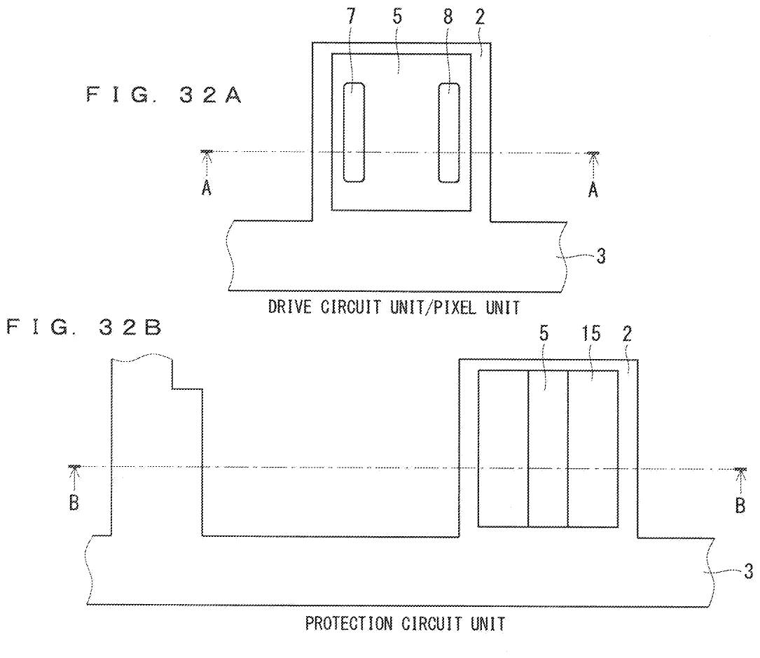

Next, as illustrated in FIGS. 23A and 23B and FIGS. 31A and 31B, O₂ ashing is performed to reduce the photoresist film thickness as a whole, and the resist of the minimum film thickness portion is removed. After that, again, the second insulating layer is etched using a dry etching method using a gas obtained by adding oxygen (O₂) to sulfur hexafluoride (SF₆), and the first contact hole 7, the second contact hole 8, and the protective layer 15 are formed as illustrated in FIGS. 24A and 24B and FIGS. 32A and 32B.

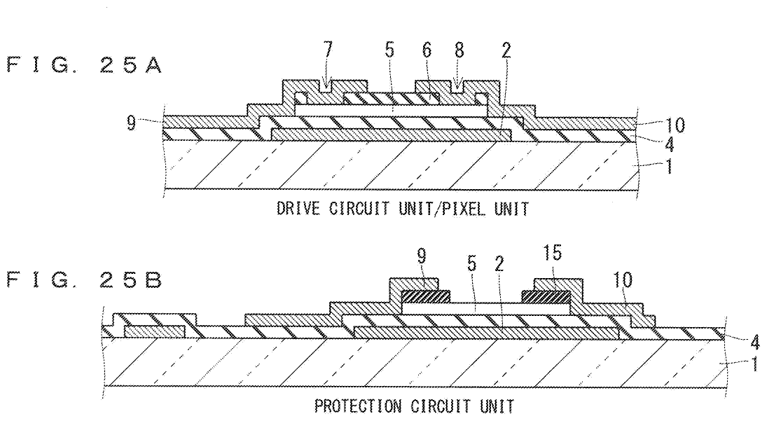

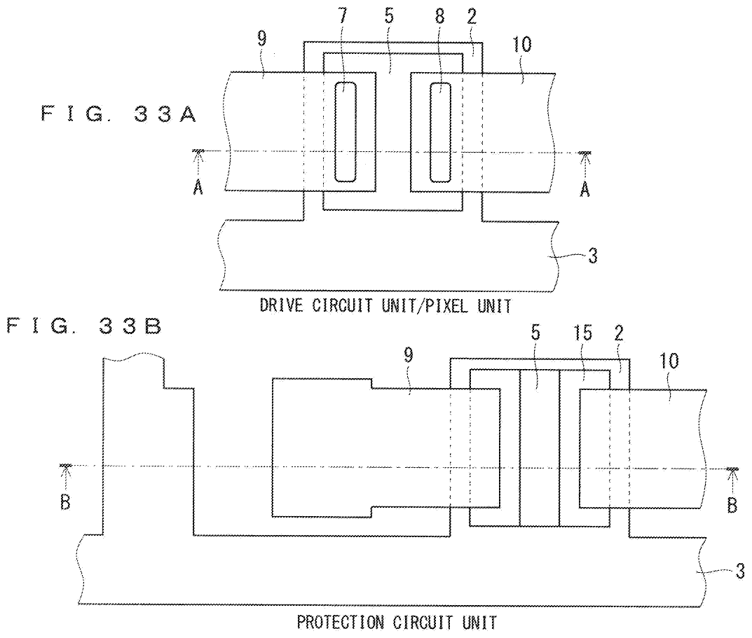

Next, films of MoNb alloy and AL-Ni—Nd alloy have been sequentially and individually formed to a thickness of 100 nm, as the second conductive film. Next, a photoresist pattern is formed in a third photoengraving process, and the laminated film of the AL alloy and the Mo alloy is etched using the photoresist pattern as a mask. By this etching, as illustrated in FIGS. 25A and 25B and FIGS. 33A and 33B, the source electrode 9 and the drain electrode 10 are formed on the channel layer 5 and the channel protective layer 6. Thereafter, the photoresist pattern is removed, and oxidation treatment is performed.

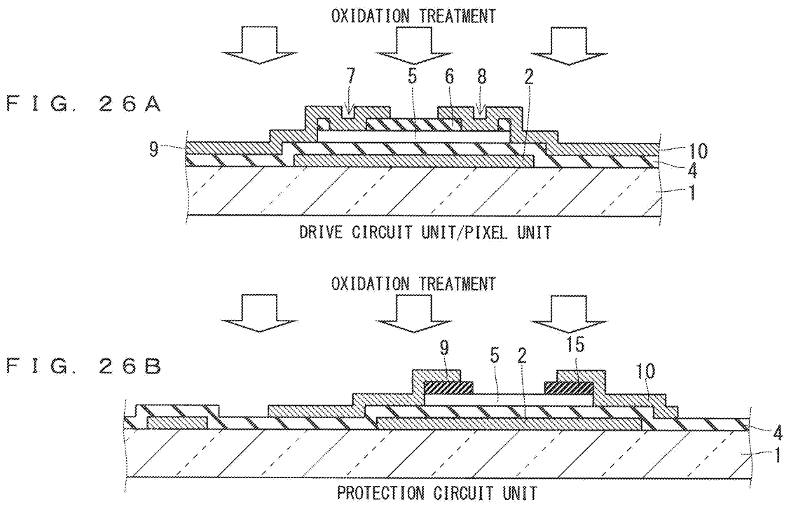

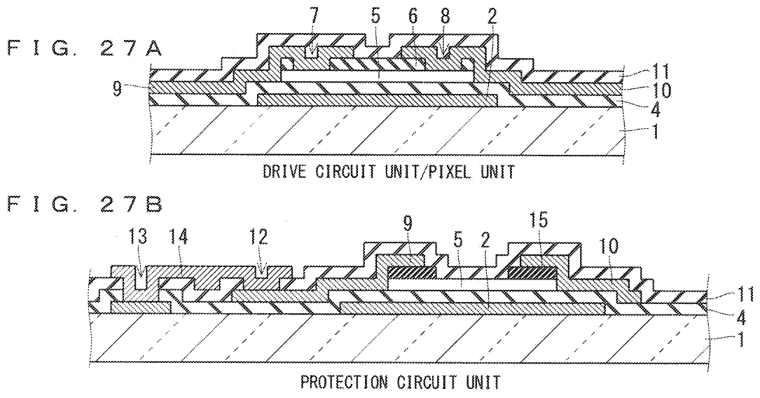

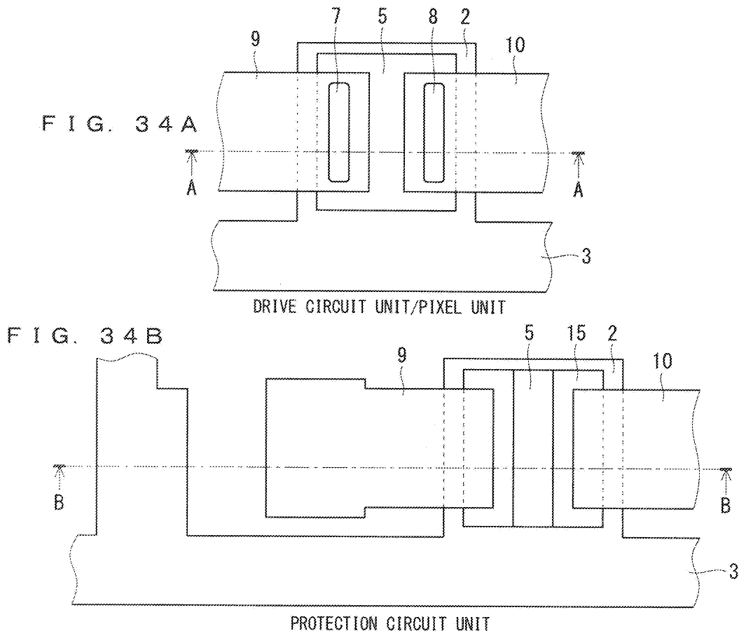

As illustrated in FIGS. 26A and 26B and FIGS. 34A and 34B, in the channel layer 5 of the protection circuit unit, oxidation is performed such that a carrier concentration of a channel portion that is not covered with the source electrode 9, the drain electrode 10, and the protective layer 15 becomes 1E+10/cm³ or less. Thereafter, the TFT array substrate illustrated in FIGS. 27A and 27B and FIGS. 35A and 35B is completed through a process similar to the manufacturing method of the first preferred embodiment.

As described above, in the TFT array substrate according to the third preferred embodiment, the TFT included in the protection circuit unit further includes the protective layer 15 formed on a part of the channel layer 5. Then, the source electrode 9 and the drain electrode 10 of the protection circuit unit have been formed on the protective layer 15 and electrically connected to the side surface portion of the channel layer 5.

Accordingly, since the connection area of the source electrode 9 and the drain electrode 10 between with the channel layer 5 is reduced, an on-current of the diode can be reduced. This enables reduction of the channel length, making it possible to reduce an area of the protection circuit unit.

### Fourth Preferred Embodiment

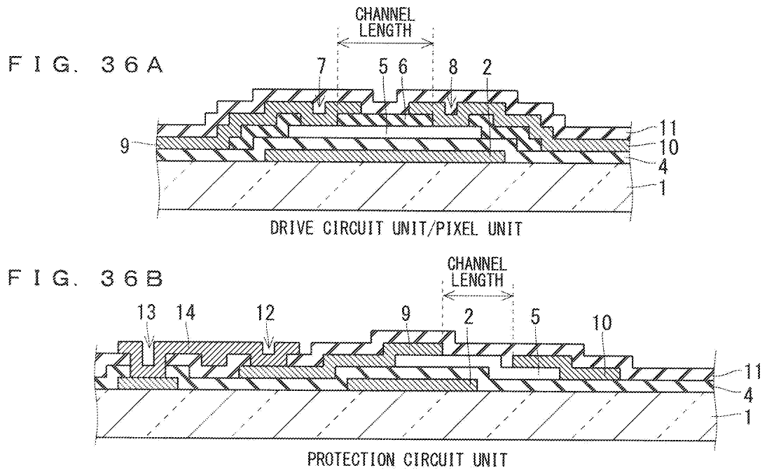

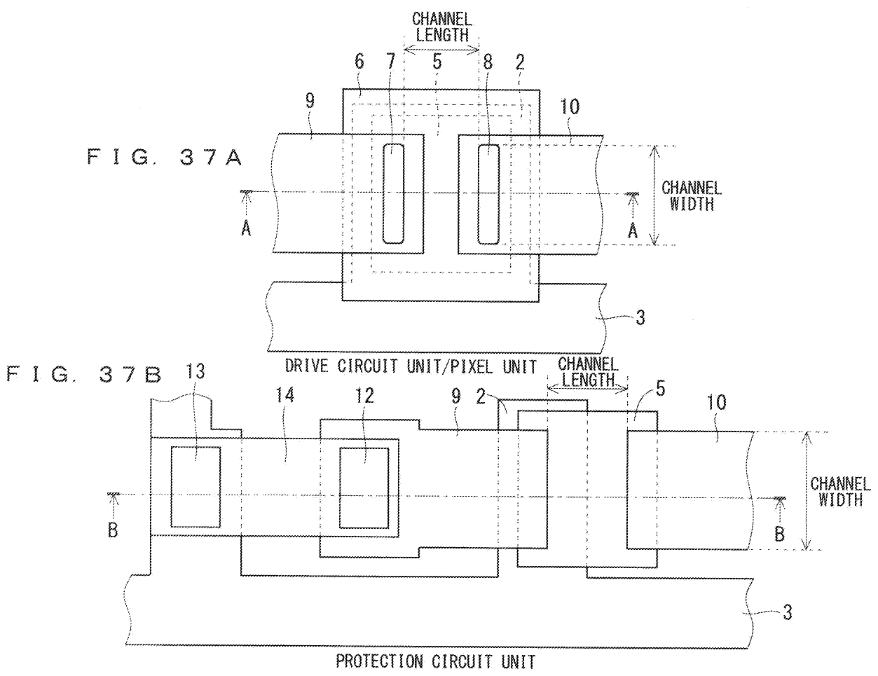

Next, a TFT array substrate according to a fourth preferred embodiment will be described. FIG. 36A is a cross-sectional view of a drive circuit unit and a pixel unit included in the TFT array substrate according to the fourth preferred embodiment. FIG. 36B is a cross-sectional view of a protection circuit unit included in the TFT array substrate according to the fourth preferred embodiment. FIG. 37A is a plan view of the drive circuit unit and the pixel unit included in the TFT array substrate according to the fourth preferred embodiment. FIG. 37B is a plan view of the protection circuit unit included in the TFT array substrate according to the fourth preferred embodiment. Here, FIG. 36A is a cross-sectional view taken along line A-A of FIG. 37A. FIG. 36B is a cross-sectional view taken along line B-B of FIG. 37B. Note that, in the fourth preferred embodiment, the same constituent elements as those described in the first to third preferred embodiments are denoted by the same reference numerals, and a description thereof will be omitted.

As illustrated in FIGS. 36A and 36B and FIGS. 37A and 37B, in the fourth preferred embodiment, in a TFT included in the protection circuit unit, a gate electrode 2 is overlapped with a part of a channel layer 5 between a source electrode 9 and a drain electrode 10 in plan view. Since the gate electrode 2 is not completely overlapped with the channel layer 5 between the source electrode 9 and the drain electrode 10, the channel layer 5 in the overlapping region functions as a diode, but the channel layer 5 in the non-overlapping region functions as a resistor rather than a diode. As a result, a nonlinear element has a diode and a resistor connected in series, and a forward resistance can be further increased. Therefore, a size of the protection circuit unit can be further reduced, and a frame can be narrowed. Note that the characteristic configuration in the fourth preferred embodiment may be combined with the configuration in the second preferred embodiment or the third preferred embodiment.

<Other Modifications>

The TFT array substrates according to the second to fourth preferred embodiments described above can also be applied to a liquid crystal display similarly to the case of the TFT array substrate according to the first preferred embodiment.

Further, the TFT array substrate according to each preferred embodiment may be applied to a display apparatus other than the liquid crystal display. For example, the TFT array substrate can be applied to an electro-optical display apparatus such as an organic electro luminescence (EL) display.

In addition, the TFT array substrate according to each preferred embodiment can also be applied to a liquid crystal display in which a silicon substrate provided with a drive circuit of a separate configuration is externally attached to the TFT array substrate, with a configuration in which the drive circuit unit is not built-in, that is, a configuration in which the drive circuit unit is omitted from the configuration of the TFT array substrate while the TFT array substrate is still provided with the TFT using the channel layer 5 made of an oxide semiconductor film in the pixel unit and the protection circuit unit.

It should be noted that the present invention can freely combine each preferred embodiment within the scope of the invention, and can deform or omit each preferred embodiment as appropriate.

While the invention has been shown and described in detail, the foregoing description is in all aspects illustrative and not restrictive. It is therefore understood that numerous modifications and variations can be devised without departing from the scope of the invention.

What is claimed is:

1. A thin film transistor substrate comprising:
a glass substrate;
a pixel unit disposed on the glass substrate; and
a protection circuit unit disposed on the glass substrate and protecting the pixel unit from electrostatic breakdown,
wherein both the pixel unit and the protection circuit unit include a thin film transistor,
the thin film transistor included in the pixel unit and the protection circuit unit includes: a gate electrode and gate wiring disposed on the glass substrate; a gate insulating layer covering the gate electrode and the gate wiring; and a channel layer overlapped with the gate electrode in plan view on the gate insulating layer,
the thin film transistor included in the pixel unit includes: a channel protective layer covering the channel layer; and a first source electrode and a first drain electrode that are overlapped with a part of the channel protective layer and are in contact with the channel layer,
the thin film transistor included in the protection circuit unit includes: a second source electrode and a second drain electrode that are in contact with the channel layer and disposed to be spaced apart from each other; and a protective insulating layer that is in contact with the channel layer and covers the second source electrode, the second drain electrode, and the channel protective layer, and
the thin film transistor substrate includes a pixel electrode electrically connected to the first drain electrode in the pixel unit.

2. The thin film transistor substrate according to claim 1, wherein the thin film transistor included in the protection circuit unit further includes a protective layer that covers a part of the channel layer and a side surface portion of the channel layer in a channel direction.

3. The thin film transistor substrate according to claim 1, wherein
the thin film transistor included in the protection circuit unit further includes a protective layer formed on a part of the channel layer, and
the second source electrode and the second drain electrode are formed on the protective layer, and electrically connected to a side surface portion of the channel layer.

4. The thin film transistor substrate according to claim 1, wherein the first source electrode, the first drain electrode, the second source electrode, and the second drain electrode are made of a single layer film or a laminated film formed of a plurality of layers using Cr, Cu, Mo, or alloy containing one of Cr, Cu, Mo.

5. The thin film transistor substrate according to claim 1, wherein, in the thin film transistor included in the protection circuit unit, the gate electrode is overlapped with a part of the channel layer between the second source electrode and the second drain electrode in plan view.

6. The thin film transistor substrate according to claim 1, wherein a metal composition of the channel layer in the pixel unit is same as a metal composition of the channel layer in the protection circuit unit.

7. The thin film transistor substrate according to claim 1, wherein an oxygen ratio of the channel layer in the pixel unit is lower than an oxygen ratio of the channel layer in the protection circuit unit.

8. The thin film transistor substrate according to claim 1, wherein a carrier concentration of the channel layer in the pixel unit is higher than a carrier concentration of the channel layer in the protection circuit unit.

9. A thin film transistor substrate comprising:
a glass substrate;
a pixel unit disposed on the glass substrate;
a drive circuit unit disposed on the glass substrate and configured to drive the pixel unit; and
a protection circuit unit disposed on the glass substrate and protecting the pixel unit from electrostatic breakdown,
wherein the pixel unit, the drive circuit unit, and the protection circuit unit all include a thin film transistor,
the thin film transistor included in the pixel unit, the drive circuit unit, and the protection circuit unit includes: a gate electrode and gate wiring disposed on the glass substrate; a gate insulating layer covering the gate electrode and the gate wiring; and a channel layer overlapped with the gate electrode in plan view on the gate insulating layer,
the thin film transistor included in the pixel unit and the drive circuit unit includes: a channel protective layer covering the channel layer; and a first source electrode and a first drain electrode that are overlapped with a part of the channel protective layer and are in contact with the channel layer,
the thin film transistor included in the protection circuit unit includes: a second source electrode and a second drain electrode that are in contact with the channel layer and disposed to be spaced apart from each other; and a protective insulating layer that is in contact with the channel layer and covers the second source electrode, the second drain electrode, and the channel protective layer, and
the thin film transistor substrate includes a pixel electrode electrically connected to the first drain electrode in the pixel unit.

10. The thin film transistor substrate according to claim 9, wherein a metal composition of the channel layer in the pixel unit and the drive circuit unit is same as a metal composition of the channel layer in the protection circuit unit.

11. The thin film transistor substrate according to claim 9, wherein an oxygen ratio of the channel layer in the pixel unit and the drive circuit unit is lower than an oxygen ratio of the channel layer in the protection circuit unit.

12. The thin film transistor substrate according to claim 9, wherein a carrier concentration of the channel layer in the pixel unit and the drive circuit unit is higher than a carrier concentration of the channel layer in the protection circuit unit.

13. A display apparatus comprising the thin film transistor substrate according to claim 1.

14. A display apparatus comprising the thin film transistor substrate according to claim 9.

15. A liquid crystal display comprising:
the thin film transistor substrate according to claim 1; and
a counter substrate disposed to face the thin film transistor substrate via a liquid crystal layer.

16. A liquid crystal display comprising:
the thin film transistor substrate according to claim 9; and
a counter substrate disposed to face the thin film transistor substrate via a liquid crystal layer.
